(19) United States
(12) Patent Application Publication
(10) Pub. No.: US 2022/0186066 A1
(43) Pub. Date: Jun. 16, 2022

(54) PROTECTION MEMBER FOR SEMICONDUCTOR, PROTECTION COMPOSITION FOR INKJET COATING-TYPE SEMICONDUCTOR, AND METHOD FOR PRODUCING SEMICONDUCTOR APPARATUS USING SAME, AND SEMICONDUCTOR APPARATUS

(71) Applicant: Mitsui Chemicals, Inc., Tokyo (JP)

(72) Inventors: Yasuharu YAMADA, Kawasaki -shi, Kanagawa (JP); Takumi SHIRAISHI, Narashino-shi, Chiba (JP); Yusuke TOMITA, Kisarazu-shi, Chiba (JP); Yugo YAMAMOTO, Chiba-shi, Chiba (JP)

(21) Appl. No.: 17/442,611

(22) PCT Filed: Mar. 26, 2020
(86) PCT No.: PCT/JP2020/013766

§ 371 Date: Sep. 24, 2021

(30) Foreign Application Priority Data
Mar. 26, 2019 (JP) 2019-059223
Mar. 28, 2019 (JP) 2019-064888

(51) Int. Cl. C09D 163/00; C09D 11/16; C09D 11/101; C08G 59/22; B41M 5/00; H05K 3/28; H01L 21/48; H01L 23/00

(52) U.S. Cl. CPC C09D 163/00; C09D 11/16; C09D 11/101; H01L 23/562; B41M 5/0023; H05K 3/287; H01L 21/481; C08G 59/22

(57) ABSTRACT

The present invention addresses the problem of providing a protection member which is for a semiconductor and has excellent pattern retention at high temperatures and moisture resistance and has good adhesion to a semiconductor circuit, etc. for long period of time. The protection member which is for a semiconductor and solves said problem, includes a cured article of an organic polymerizable compound having a functional group containing an oxygen atom and/or a nitrogen atom. The absolute value of the difference between the linear expansion coefficient at 150° C. of the cured article and the linear expansion coefficient at 25° C. of the cured article is 55 or less.

### TECHNICAL FIELD

The present invention relates to a protection member for a semiconductor (hereinafter also referred to as “semiconductor protection member”), an inkjet coating-type protection composition for a semiconductor (hereinafter also referred to as “inkjet coating-type semiconductor protection composition”), and a method for producing a semiconductor device using the composition, and a semiconductor device.

### BACKGROUND ART

Conventionally, a polyimide layer has been widely used as a protective layer for protecting a semiconductor or the like. In recent years, the configuration of semiconductor devices has become complicated, which requires, for example, forming of a protective layer, an insulating layer, and the like of a semiconductor in a pattern. For forming a conventional polyimide layer in a pattern, the polyimide or the precursor thereof is applied to the entire surface by a spin coating method and cured. It is common practice after the spin coating to process the obtained layer into a desired pattern by photolithography, etching, or the like. However, such a method is complicated and time-consuming. In addition, as a part of the resin is removed by the etching or the like, the efficiency of material utilization is low. There is thus a demand for a simpler method to form the protective layer, insulating layer, and the like of a semiconductor device in a pattern.

Recently, cationic polymerizable resin compositions containing epoxy resins have been proposed as various adhesives, sealing agents, potting agents, coating agents, and the like (Patent Literature (hereinafter abbreviated as “PTL”) 1). In addition, a resin composition containing a silicon compound has also been proposed as a resist for nanoimprinting (PTL 2).

### CITATION LIST

### Patent Literature

### PTL 1

WO2017/094584

### PTL 2

Japanese Patent No. 5757242

### SUMMARY OF INVENTION

### Technical Problem

As a method for readily forming a protective layer or an insulating layer of a semiconductor device or the like into a desired pattern without performing photolithography or the like, it is conceivable, for example, to apply the cationic polymerizable resin composition described in PTL 1 by an inkjet method. However, the cationic polymerizable resin composition of PTL 1 has a high viscosity and is not suitable for printing by an inkjet method. In addition, the cured product of the cationic polymerizable resin composition of PTL 1 is easily peeled off over time when used under high humidity. The present inventors have found that a cationic polymerizable resin composition containing a common epoxy resin as described in PTL 1 tend to contain chlorine derived from the material (especially epoxy resins), and when such a cationic polymerizable resin composition is used for the protective layer or insulating layer of a semiconductor device or the like, chlorine ions migrate and easily cause corrosion of metal wiring or the like.

It is also conceivable to apply the resin composition described in PTL 2 by an inkjet method, but this resin composition also has a high viscosity and is not suitable for printing by an inkjet method. The resin composition in PTL 2, for example, tends to be insufficiently cured and deformed at high temperatures.

An object of the present invention is to provide a semiconductor protection member that has excellent pattern retention at high temperatures and moisture resistance and also has suitable adhesion to a semiconductor circuits for a long period of time.

### Solution to Problem

The present invention provides a semiconductor protection member as follows.

[1] A semiconductor protection member, containing: a cured product of an organic polymerizable compound having a functional group, the functional group containing at least one of an oxygen atom and a nitrogen atom, in which an absolute value of a difference between a coefficient of linear expansion of the cured product at 150° C. and the coefficient of linear expansion of the cured product at 25° C. is 55 or less.

[2] The semiconductor protection member according to [1], further containing: a Si—O bond at least in a part thereof.

[3] The semiconductor protection member according to [1] or [2], in which: a total amount of anions detected when 0.25 g of the cured product is immersed in 10 mL of water at 100° C. and subjected to extraction for 20 hours is 50 ppm or less.

[4] The semiconductor protection member according to any one of [1] to [3], in which: pH of water after 0.25 g of the cured product is immersed in 10 mL of the water at 100° C. and left for 20 hours is 4.4 to 8.7.

[5] The semiconductor protection member according to any one of [1] to [4], in which: the cured product has a water absorption percentage of 2% or less.

[6] The semiconductor protection member according to any one of [1] to [5], in which: the organic polymerizable compound is at least one compound selected from the group consisting of epoxy compounds, urethane compounds, (meth)acrylic compounds, imide compounds, and benzoxazole.

The present invention provides an inkjet coating-type semiconductor protection composition as follows.

[7] An inkjet coating-type semiconductor protection composition, containing: a cationic polymerizable compound (A) that contains an epoxy compound having two or more epoxy groups per molecule and an oxetane compound having two or more oxetane groups per molecule; a silane coupling agent (B) having a Si—O—Si skeleton, an epoxy group, and an alkoxy group per molecule and having a weight average molecular weight of 1,000 or more; a photocationic polymerization initiator (C); and a thermalcationic polymerization initiator (D), in which the inkjet coating-type semiconductor protection composition has a viscosity of 5 to 50 mPa·s measured at 25° C. and 20 rpm by using an E-type viscometer.

[8] The inkjet coating-type semiconductor protection composition according to [7], in which: the inkjet coating-type semiconductor protection composition has a surface tension of 20 to 40 mN/m.

[9] The inkjet coating-type semiconductor protection composition according to [7] or [8], in which: the silane coupling agent (B) has two or more epoxy groups per molecule, and two or more alkoxy groups per molecule.

[10] The inkjet coating-type semiconductor protection composition according to any one of [7] to [9], in which: the inkjet coating-type semiconductor protection composition contains 1 to 20 parts by mass of the silane coupling agent (B), 0.1 to 10 parts by mass of the photocationic polymerization initiator (C), and 0.1 to 10 parts by mass of the thermalcationic polymerization initiator (D), based on 100 parts by mass of the cationic polymerizable compound (A); and an amount of the thermalcationic polymerization initiator (D) is 10 to 50 parts by mass based on 100 parts by mass of the photocationic polymerization initiator (C).

The present invention provides an inkjet coating-type semiconductor protection composition and a cured product thereof as follows.

[11] An inkjet coating-type semiconductor protection composition, containing: an alicyclic epoxy compound (K) having two or more epoxy groups per molecule; a photocationic polymerization initiator (L); and a silane coupling agent (M), in which the inkjet coating-type semiconductor protection composition has chloride ion content of 50 ppm or less, and a viscosity of 5 to 50 mPa·s measured at 25° C. and 20 rpm by using an E-type viscometer.

[12] The inkjet coating-type semiconductor protection composition according to [11], in which: the inkjet coating-type semiconductor protection composition has a surface tension of 20 to 40 mN/m.

[13] The inkjet coating-type semiconductor protection composition according to [11] or [12], in which: the alicyclic epoxy compound (K) has a cycloalkene oxide structure represented by the following general formula

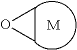

where M represents an alicyclic structure having 4 to 8 carbon atoms.

[14] The inkjet coating-type semiconductor protection composition according to any one of [11] to [13], in which: the inkjet coating-type semiconductor protection composition contains 0.1 to 10 parts by mass of the photocationic polymerization initiator (L) and 1 to 20 parts by mass of the silane coupling agent (M), based on 100 parts by mass of the alicyclic epoxy compound (K).

[15] A cured product of the inkjet coating-type semiconductor protection composition according to any one of [11] to [14], in which: the cured product has a loss tangent (tan δ) of 0.01 or more in a temperature range of 25° C. to 150° C. when dynamic viscoelasticity measurement is performed at a frequency of 1.6 Hz.

The present invention also provides a semiconductor device as follows.

[16] A semiconductor device, including: a semiconductor circuit board provided with a circuit disposed on at least one surface thereof; a cured product layer of the inkjet coating-type semiconductor protection composition according to any one of [7] to [14], the cured product layer covering at least a part of the semiconductor circuit board; and a semiconductor mold resin layer disposed on the cured product layer.

[17] A semiconductor device, including: a board with metal wiring disposed thereon; a cured product layer of the inkjet coating-type semiconductor protection composition according to any one of [7] to [14], the cured product layer covering at least a part of the metal wiring of the board; and a circuit portion disposed on the cured product layer so as to be electrically connected to the metal wiring.

The present invention also provides a method for producing a semiconductor device as follows.

[18] A method for producing a semiconductor device, the method including preparing a semiconductor circuit board or a board including metal wiring; applying the inkjet coating-type semiconductor protection composition according to any one of [7] to [14] on the semiconductor circuit board or the metal wiring of the board by an inkjet method; photo curing of curing a coating film of the inkjet coating-type semiconductor protection composition by irradiating the coating film with active light within 60 seconds after the applying; and thermal curing of curing the coating film after the photo curing with heat.

### Advantageous Effects of Invention

The semiconductor protection member of the present invention has excellent pattern retention at high temperatures and suitable adhesion to a semiconductor circuit or the like for a long period of time.

### DESCRIPTION OF EMBODIMENTS

1. Inkjet Coating-Type Semiconductor Protection Composition

An inkjet coating-type protection composition for a semiconductor (i.e., inkjet coating-type semiconductor protection composition, hereinafter also referred to simply as a “composition”) of the present invention is a composition to be applied by an inkjet method to form, for example, a layer for protection and insulation of a semiconductor device. The compositions of the present invention include two compositions as follows. Hereinafter, each composition will be described in detail.

1-1. First Composition

Polyimide resins have been mainly used for the protective layer or insulating layer of a semiconductor device or the like. However, it is difficult to form a polyimide resin directly into a pattern, and patterning is commonly performed by, for example, photolithography or etching.

Meanwhile, the first composition (A) has the advantages as follows. The first composition contains the following: (A) a cationic polymerizable compound containing an epoxy compound and an oxetane compound; (B) a silane coupling agent having a Si—O—Si skeleton, an epoxy group, and an alkoxy group per molecule and having a weight average molecular weight of 1,000 or more; (C) a photocationic polymerization initiator; and (D) a thermalcationic polymerization initiator. The first composition has a viscosity of 5 to 50 mPa·s measured at 25° C. and 20 rpm by using an E-type viscometer. The first composition has a sufficiently low viscosity, and thus can be applied by an inkjet method to form a film in a desired pattern.

In addition, the first composition contains a silane coupling agent (B) having a particular structure. This configuration improves the adhesion between the cured product of the composition and a semiconductor device, and the cured product is less likely to be peeled off from the semiconductor circuit board or the like even in a high temperature environment or the like. The first composition also contains a photocationic polymerization initiator (C), and a thermalcationic polymerization initiator (D) described above. The first composition thus has excellent curability by light and heat, and can be temporarily cured by light irradiation, for example. The cured product thus can be formed in the desired pattern. In addition, the cured product of the first composition is not easily deformed even in a high temperature environment. The semiconductor is thus sufficiently protected for a long period of time. In the following, the first composition will be described in detail.

(A) Cationic Polymerizable Compound

The cationic polymerizable compound (A) contains an epoxy compound having two or more epoxy groups per molecule and an oxetane compound having two or more oxetane groups per molecule. The total amount of the cationic polymerizable compound (A) based on 100 parts by mass of the total amount of the composition is preferably 70 to 99 parts by mass, more preferably 80 to 99 parts by mass, and even more preferably 90 to 99 parts by mass.

The epoxy compound contained in the cationic polymerizable compound (A) may be any compound that has two or more epoxy groups in one molecule thereof, but preferably a compound that is liquid at room temperature. The epoxy compound may be an alicyclic epoxy compound, an aliphatic epoxy compound, or an aromatic epoxy compound. The cationic polymerizable compound (A) may contain only one type of epoxy compound, or two or more types of epoxy compound. The number of epoxy groups contained in each epoxy compound is preferably 2 to 4, more preferably 2 to 3, per molecule.

Examples of the alicyclic epoxy compound include compounds having a cycloalkene oxide structure. A cycloalkene oxide structure is obtained by epoxidizing a cycloalkene with an oxidizing agent such as a peroxide, and has an aliphatic ring and an epoxy group composed of an oxygen atom and two carbon atoms that are part of the aliphatic ring. Examples of the cycloalkene oxides include cyclohexene oxide and cyclopentene oxide, and cyclohexene oxide is preferred.

The number of cycloalkene oxide structures in one molecule of the alicyclic epoxy compound may be one (monofunctional) or two or more (polyfunctional). In particular, the number of cycloalkene oxide structures in one molecule of the alicyclic epoxy compound is preferably two or more (polyfunctional) from the viewpoint that the oxygen atom content described below can be readily increased and an excellent heat resistance can also be provided.

An example of the alicyclic epoxy compound having a cycloalkene oxide structure is a compound represented by the following general formula (A-1).

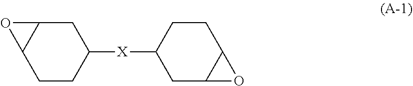

X in the general formula (A-1) is a single bond or a linking group. The linking group is preferably selected in such a way that the weight average molecular weight and the oxygen atom content of the compound represented by the formula (A-1) fall within the ranges described below. Examples of the linking group include divalent hydrocarbon groups, carbonyl group, ether group (ether bond), thioether group (thioether bond), ester group (ester bond), carbonate group (carbonate bond), amide group (amide bond), and groups each having a plurality of these groups linked to each other.

Examples of the divalent hydrocarbon groups include alkylene groups having 1 to 18 carbon atoms or divalent alicyclic hydrocarbon groups. Examples of the alkylene groups having 1 to 18 carbon atoms include methylene group, methylmethylene group, dimethylmethylene group, ethylene group, propylene group, and trimethylene group. Examples of the divalent alicyclic hydrocarbon groups include divalent cycloalkylene groups (including cycloalkylidene groups), such as 1,2-cyclopentylene group, 1,3-cyclopentylene group, cyclopentylidene group, 1,2-cyclohexylene group, 1,3-cyclohexylene group, 1,4-cyclohexylene group, and cyclohexylidene group.

In particular, X is preferably a single bond or a linking group having an oxygen atom. More preferably, the linking group having an oxygen atom is —CO— (carbonyl group), —O—CO—O— (carbonate group), —COO— (ester group), —O— (ether group), —CONH— (amide group), a group having a plurality of these groups linked to each other, or a group having one or more of these groups linked to one or more of the divalent hydrocarbon groups.

Examples of the alicyclic epoxy compound represented by the general formula (A-1) include the compounds below. In the following formulas, 1 is an integer of 1 to 10, m is an integer of 1 to 30, R is an alkylene group having 1 to 8 carbon atoms (preferably an alkylene group having 1 to 3 carbon atoms, such as a methylene group, an ethylene group, a propylene group and an isopropylene group), and n1 and n2 are each an integer of 1 to 30.

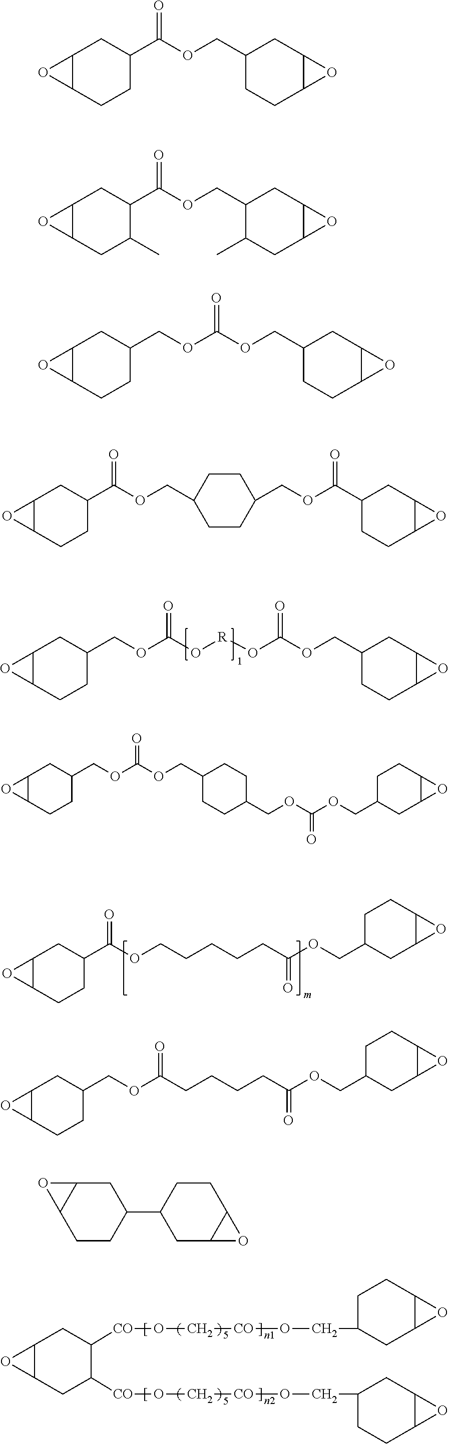

Examples of commercially available alicyclic epoxy compounds having a cycloalkene oxide structure include Celloxide 2021P, Celloxide 2081, Celloxide 8000, and Celloxide 8010 (all manufactured by Daicel Corporation).

Examples of the aliphatic epoxy compound include polyglycidyl ethers of aliphatic polyhydric alcohols or alkylene oxide adducts thereof. The aliphatic polyhydric alcohol may be a chain alcohol or may partially have a cyclic structure (excluding the alicyclic epoxy compound having a cycloalkene oxide structure described above). The aliphatic alcohol (including the aliphatic polyhydric alcohol) is preferably a chain alcohol, and a diglycidyl ether of an alkanediol or an alkylene oxide adduct thereof is more preferred, from the viewpoint that the composition is more likely to have a lower viscosity.

Examples of the aliphatic epoxy compound also include diglycidyl ethers of alkanediols having 4 to 6 carbon atoms, such as 1,4-butanediol diglycidyl ether, neopentyl glycol diglycidyl ether, and 1,6-hexanediol diglycidyl ether; triglycidyl ethers of, for example, glycerin and trimethylolpropane; a tetraglycidyl ether of sorbitol; a hexaglycidyl ether of dipentaerythritol; diglycidyl ethers of, for example, polyethylene glycol and polypropylene glycol; and polyglycidyl ethers of alkylene oxide adducts (polyether polyols) of, for example, propylene glycol and trimethylolpropane.

Examples of commercially available aliphatic epoxy compounds include SR-PG, SR-2EGS, SR-BEGS, SR-14BJ, and SY-25L (manufactured by Sakamoto Yakuhin Kogyo Co., Ltd.), EPOGOSEY 2EH, EPOGOSEY HD (D), EPOGOSEY NPG (D), and EPOGOSEY BD (D) (manufactured by Yokkaichi Chemical Company Limited), and DENACOL EX-121, DENACOL EX-212L, and DENACOL EX-214L (manufactured by Nagase ChemteX Corporation).

Examples of the aromatic epoxy compound include glycidyl ethers of alcohols (including polyhydric alcohols) containing an aromatic ring. Examples of the aromatic epoxy compound also include bisphenol A epoxy resin, bisphenol E epoxy resin, bisphenol F epoxy resin, bisphenol S epoxy resin, bisphenol O epoxy resin, 2,2′-diallyl-bisphenol A epoxy resin, propylene oxide-adduct bisphenol A epoxy resin, resorcinol epoxy resin, biphenyl epoxy resin, sulfide epoxy resin, diphenyl ether epoxy resin, naphthalene epoxy resin, phenol novolac epoxy resin, ortho-cresol novolac epoxy resin, biphenyl novolac epoxy resin, and naphthalene phenol novolac epoxy resin.

For any of the above described epoxy compounds, the weight average molecular weight thereof is preferably 180 or more, more preferably 190 or more, and even more preferably 200 or more. The upper limit of the weight average molecular weight of the epoxy compound is appropriately selected according to the viscosity of the composition, but is preferably 400 or less. A weight average molecular weight of the epoxy compound of 180 or more can minimize volatilization of the epoxy compound from the composition. As a result, during the application of the composition by the inkjet method, the component amount in the composition is less likely to change, and the working environment is less likely to be impaired. The weight average molecular weight can be measured in terms of polystyrene by gel permeation chromatography (GPC).

The oxygen atom content (represented by the equation (1) below) of the epoxy compound is preferably 15% or more, more preferably 20% or more. On the other hand, the oxygen atom content is preferably 30% or less.

Oxygen atom content (%)=Total mass of oxygen atoms in one molecule/Weight average molecular weight×100 Equation (1)

When the oxygen atom content of the epoxy compound is 15% or more, the polarity of the epoxy compound increases, lowering the affinity with an adhesive and a rubber material (such as ethylene propylene butadiene rubber) which have a low polarity and are used in the head portion of the inkjet device. As a result, the adhesive and rubber material are less likely to swell, and their degradation (damage to the device) is less likely to occur.

The total mass of oxygen atoms in one molecule of an epoxy compound can be calculated by specifying the structure of the epoxy compound by GC-MS, NMR, or other methods, specifying the number of oxygen atoms in one molecule of the compound, and then multiplying the number by the atomic weight of an oxygen atom. The oxygen atom content of an epoxy compound can be calculated by applying the obtained total mass of oxygen atoms and the weight average molecular weight measured by the GPC method to the above equation (1). The oxygen atom content of an epoxy compound can be adjusted by the number of epoxy groups per molecule and the number of groups containing oxygen atoms.

The amount of the epoxy compound contained in the cationic polymerizable compound (A) is preferably 20 to 80 parts by mass, more preferably 30 to 70 parts by mass, and even more preferably 40 to 60 parts by mass, based on the total amount of the cationic polymerizable compound (A). When the amount of the epoxy compound is 40 parts by mass or more, the strength of the cured product of the composition is more likely to increase. When the amount of the epoxy compound is 60 parts by mass or less, the viscosity of the composition is more likely to fall within a desired range.

The oxetane compound contained in the cationic polymerizable compound (A) may be any compound that has two or more oxetane groups in one molecule thereof, and the oxetane compound may have any structure. The oxetane compound is preferably a compound that is liquid at room temperature. The cationic polymerizable compound (A) may contain only one type of oxetane compound, or two or more types of oxetane compound. The number of oxetane groups contained in the oxetane compound is preferably 2 to 4, more preferably 2 to 3 per molecule.

Examples of the oxetane compound include compounds represented by the following general formulas (A-2) and (A-3).

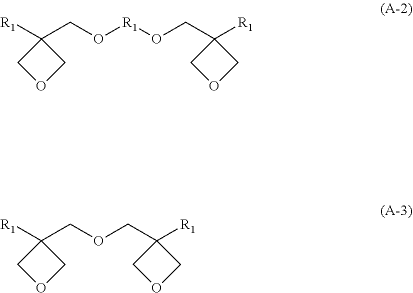

In the general formulas (A-2) and (A-3), R₁ is individually a hydrogen atom, an alkyl group having 1 to 6 carbon atoms, an allyl group, an aryl group, an aralkyl group, a furyl group or a thienyl group; and R₂ is a divalent organic residue. R₁ and R₂ are preferably selected so as to satisfy the weight average molecular weight and oxygen atom content described below.

Examples of the alkyl group having 1 to 6 carbon atoms include methyl group, ethyl group, propyl group, butyl group, pentyl group, hexyl group, and cyclohexyl group. Examples of the aryl group include phenyl group, naphthyl group, tolyl group, and xylyl group. Examples of the aralkyl group include benzyl group and phenethyl group.

Examples of the divalent organic residue include alkylene group, polyoxyalkylene group, phenylene group, xylylene group, and structures represented by the following general formulas.

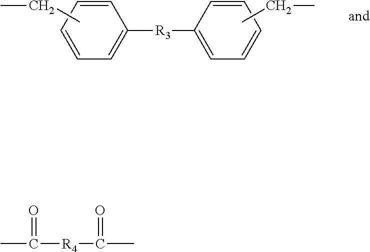

R₃ in the general formulas is an oxygen atom, a sulfur atom, —CH₂—, —NH—, —SO—, —SO₂—, —(CF₃)₂— or —C(CH₃)₂—.

R₄ in the general formula is an alkylene group having 1 to 6 carbon atoms or an arylene group. Examples of the alkylene groups include alkylene groups having 1 to 15 carbon atoms, such as methylene group, ethylene group, propylene group, butylene group, and cyclohexylene group. The polyoxyalkylene group is preferably a polyoxyalkylene group having 4 to 30 carbon atoms, more preferably 4 to 8 carbon atoms, and examples thereof include polyoxyethylene group and polyoxypropylene group.

Examples of commercially available oxetane compounds include OXT-121, OXT-221 (all manufactured by Toagosei Co., Ltd.), and OXBP (manufactured by Ube Industries, Ltd.).

The weight average molecular weight of the oxetane compound is preferably 180 or more, more preferably 190 or more, and even more preferably 200 or more. The upper limit of the weight average molecular weight of the oxetane compound is appropriately selected according to the viscosity of the composition, but is preferably 400 or less. A weight average molecular weight of the oxetane compound of 180 or more can minimize volatilization of the oxetane compound from the composition. As a result, during the application of the composition by the inkjet method, the component amount in the composition is less likely to change, and the working environment is less likely to be impaired. The weight average molecular weight can be measured in terms of polystyrene by gel permeation chromatography (GPC).

The oxygen atom content of the oxetane compound is preferably 15% or more, more preferably 20% or more. On the other hand, the oxygen atom content is preferably 30% or less. The oxygen atom content can be obtained by the above equation (1). When the oxygen atom content of the oxetane compound is 15% or more, the polarity of the oxetane compound increases, thereby reducing degradation of an adhesive and the like having a low polarity used in the head portion of the inkjet device (reducing damage to the device). For increasing the oxygen atom content of the oxetane compound, the number of oxetanyl groups per molecule of the oxetane compound and/or the number of oxygen atoms in the oxygen containing group, such as R₂ in the general formula (A-2), may be increased.

The amount of the oxetane compound is preferably 30 to 80 parts by mass, more preferably 40 to 70 parts by mass, and even more preferably 50 to 60 parts by mass, based on the total amount of the cationic polymerizable compound (A). When the amount of the oxetane compound is 50 parts by mass or more, the viscosity of the composition is more likely to fall within a desired range. When the amount of oxetane compound is 60 parts by mass or less, the amount the epoxy compound relatively increases, and thus the strength of the cured product of the composition is more likely to increase.

(B) Silane Coupling Agent

The silane coupling agent (B) has a Si—O—Si skeleton, an epoxy group, and an alkoxy group per molecule and has a weight average molecular weight of 1,000 or more. The weight average molecular weight of the silane coupling agent is more preferably 1,000 to 5,000, even more preferably 1,500 to 2,500. When the silane coupling agent (B) has a siloxane skeleton (Si—O—Si skeleton) and has a weight average molecular weight of 1,000 or more, the silane coupling agent (B) is more likely to be unevenly distributed on the surface of the metal wiring and the like of a semiconductor device, and the adhesion of the cured product of the composition to the metal wiring and the like of the semiconductor device is more likely to improve even in a high temperature and high humidity environment. A silane coupling agent (B) having an epoxy group is more likely to form a network with the cationic polymerizable compound (A), and less likely to emerge from the cured product. A silane coupling agent having a weight average molecular weight of 5,000 or less is more likely to allow the viscosity of the composition to fall within a desired range. The weight average molecular weight of the silane coupling agent can be measured in terms of polystyrene by gel permeation chromatography (GPC).

The amount of the silane coupling agent (B) contained in the composition is preferably 1 to 20 parts by mass, more preferably 10 to 20 parts by mass, based on 100 parts by mass of the above described cationic polymerizable compound (A). When the amount of the silane coupling agent is within the above ranges, the adhesion between the film obtained from the composition and a semiconductor circuit or the like is more likely to improve.

The silane coupling agent (B) may be any compound that has a siloxane skeleton (Si—O—Si skeleton), an alkoxy group bonded to Si of the siloxane skeleton, and an epoxy group, and has a molecular weight in the above range. The silane coupling agent (B) is obtained by polymerizing, for example, dialkoxysilane, trialkoxysilane, or tetraalkoxysilane. During the polymerization, using a monomer having an epoxy group in a part thereof can introduce the epoxy group into the molecule. The siloxane skeleton (Si—O—Si skeleton) may be a skeleton in which Si and O are linearly linked, or a skeleton in which Si and O are linked in a three-dimensional network.

The silane coupling agent (B) has at least one alkoxy group in one molecule thereof, and preferably has two or more alkoxy groups from the viewpoint of improving the adhesion between the cured product obtained from the composition and a semiconductor circuit or the like. The silane coupling agent (B) has at least one epoxy group in one molecule thereof, and preferably has two or more epoxy groups from the viewpoint of forming a network with the cationic polymerizable compound (A). A group other than the alkoxy group may be further bonded to the siloxane skeleton, and for example, a (meth)acryloyl group, a phenyl group, a mercapto group, or an oxetanyl group may be further bonded to the siloxane skeleton. The composition may contain only one type of silane coupling agent (B), or two or more types of silane coupling agent (B).

The silane coupling agent (B) may be prepared by polymerizing at least one of various alkoxysilanes, or may be a commercially available product. Examples of the commercially available product include KR-500, KR-510, KR-516, KR-517, X-40-2670, X-12-981S, and X-12-9845 (all manufactured by Shin-Etsu Chemical Co., Ltd.).

(C) Photocationic Polymerization Initiator

The photocationic polymerization initiator (C) may be any compound that generates active species capable of initiating cationic polymerization by irradiation with an active light such as ultraviolet light. The amount of the photocationic polymerization initiator (C) contained in the composition is preferably 0.1 to 10 parts by mass, more preferably 0.1 to 5 parts by mass, based on 100 parts by mass of the cationic polymerizable compound (A).

Examples of the photocationic polymerization initiator include aromatic sulfonium salts, aromatic iodonium salts, aromatic diazonium salts, and aromatic ammonium salts. The anion moiety of the salts is preferably BF₄—, PX₆— (X is a fluorine atom or a fluoroalkyl group), SbF₆—, or BX₄— (X is a phenyl group substituted with at least two or more fluorine atoms or a trifluoromethyl group). The composition may contain only one type of photocationic polymerization initiator (C), or two or more types of photocationic polymerization initiator (C).

Examples of the aromatic sulfonium salts include bis[4-(diphenylsulfonio)phenyl]sulfide bis(hexafluorophosphate), bis[4-(diphenylsulfonio)phenyl]sulfide bis(hexafluoroantimonate), bis[4-(diphenylsulfonio)phenyl]sulfide bis(tetrafluoroborate), bis[4-(diphenylsulfonio)phenyl]sulfide tetrakis(pentafluorophenyl)borate, diphenyl-4-(phenylthio)phenylsulfonium hexafluorophosphate, diphenyl-4-(phenylthio)phenylsulfonium hexafluoroantimonate, and diphenyl-4-(phenylthio)phenylsulfonium tetrafluoroborate.

Examples of the aromatic iodonium salts include diphenyliodonium hexafluorophosphate, diphenyliodonium hexafluoroantimonate, diphenyliodonium tetrafluoroborate, diphenyliodonium tetrakis(pentafluorophenyl)borate, bis(dodecylphenyl)iodonium hexafluorophosphate, bis(dodecylphenyl)iodonium hexafluoroantimonate, bis(dodecylphenyl)iodonium tetrafluoroborate, and bis(dodecylphenyl)iodonium tetrakis(pentafluorophenyl)borate.

Examples of the aromatic diazonium salts include phenyldiazonium hexafluorophosphate, phenyldiazonium hexafluoroantimonate, phenyldiazonium tetrafluoroborate, and phenyldiazonium tetrakis(pentafluorophenyl)borate.

Examples of the aromatic ammonium salts include 1-benzyl-2-cyanopyridinium hexafluorophosphate and 1-benzyl-2-cyanopyridinium hexafluoroantimonate.

Examples of commercially available photocationic polymerization initiators include Irgacure 250, Irgacure 270, and Irgacure 290 (manufactured by BASF), CPI-100P, CPI-101A, CPI-200K, CPI-210S, CPI-310B, CPI-310FGh, and CPI-400PG (manufactured by San-Apro Ltd.), and SP-150, SP-170, SP-171, SP-056, SP-066, SP-130, SP-140, SP-601, SP-606, and SP-701 (manufactured by ADEKA CORPORATION). In particular, sulfonium salts such as Irgacure 270, Irgacure 290, CPI-100P, CPI-101A, CPI-200K, CPI-210S, CPI-310B, CPI-310FG, CPI-400PG, SP-150, SP-170, SP-171, SP-056, SP-066, SP-601, SP-606, and SP-701 are preferred.

(D) Thermalcationic Polymerization Initiator

The thermalcationic polymerization initiator (D) may be any compound that generates active species capable of initiating cationic polymerization by heating. The amount of the thermalcationic polymerization initiator (D) is preferably 0.1 to 10 parts by mass, more preferably 0.1 to 5 parts by mass, based on 100 parts by mass of the cationic polymerizable compound (A). The amount of the thermalcationic polymerization initiator (D) is preferably 10 to 50 parts by mass, more preferably 10 to 20 parts by mass, based on 100 parts by mass of the photocationic polymerization initiator (C). When the ratio of the amount of the thermal cationic polymerization initiator (D) to the amount of the photocationic polymerization initiator (C) is within the above range, the curability of the composition by light and heat is more likely to improve.

As the thermal cationic polymerization initiator (D), a known cationic polymerization initiator can be used. Examples of the thermal cationic polymerization initiator (D) include sulfonium salts, phosphonium salts, quaternary ammonium salts, diazonium salts, and iodonium salts. In particular, quaternary ammonium salts and sulfonium salts are preferred. The anion moiety of the salts is preferably, for example, AsF₆⁻, SbF₆⁻, PF₆⁻, and B(C₆F₅)⁴⁻. The composition may contain only one type of thermalcationic polymerization initiator (D), or two or more types of thermalcationic polymerization initiator (D).

Specific examples of the sulfonium salts include triphenylsulfonium boron tetrafluoride, triphenylsulfonium antimony hexafluoride, triphenylsulfonium arsenic hexafluoride, tri(4-methoxyphenyl)sulfonium arsenic hexafluoride, and diphenyl(4-phenylthiophenyl)sulfonium arsenic hexafluoride.

Specific examples of the phosphonium salts include ethyltriphenylphosphonium antimony hexafluoride and tetrabutylphosphonium antimony hexafluoride.

Specific examples of the quaternary ammonium salts include N,N-dimethyl-N-benzylanilinium antimony hexafluoride, N,N-diethyl-N-benzylanilinium boron tetrafluoride, N,N-dimethyl-N-benzylpyrizinium antimony hexafluoride, N,N-diethyl-N-benzylpyrizinium trifluoromethanesulfonic acid, N,N-dimethyl-N-(4-methoxybenzyl)pyrizinium antimony hexafluoride, N,N-diethyl-N-(4-methoxybenzyl)pyrizinium antimony hexafluoride, N,N-diethyl-N-(4-methoxybenzyl)toluidinium antimony hexafluoride, and N,N-dimethyl-N-(4-methoxybenzyl)toluidinium antimony hexafluoride.

Examples of commercially available thermalcationic polymerization initiators (D) include K-PURE CXC-1612 (manufactured by King Industries, Inc.), CXC-1613, CXC-1614, CXC-1615, CXC-1756, CXC-1765, CXC-1820, CXC-1821, TAG-2172, TAG-2179, TAG-2507, TAG-2678, TAG-2689, TAG-2690, and TAG-2713 (all manufactured by King Industries, Inc.), and SAN-AID SI-B2A, SI-B3, SI-B3A, SI-B4, SI-B5, SI-B7, SI-45, SI-60, SI-80, SI-100, SI-110, SI-110L, SI-145, SI-150, SI-160, SI-180L, SI-300, and SI-360 (manufactured by SANSHIN CHEMICAL INDUSTRY CO., LTD.).

(E) Additional Component

The composition of the present invention may additionally contain component(s) other than the components (A) to (D) as long as the effects of the present invention are not impaired. Examples of the additional components include sensitizers and leveling agents.

The sensitizer is a compound having a function of further improving the efficiency of generating active species of the photocationic polymerization initiator (C) and the thermalcationic polymerization initiator (D) to further promote the curing reaction of the composition. Examples of the sensitizers include thioxanthone compounds such as 2,4-diethylthioxanthone, benzophenone compounds such as 2,2-dimethoxy-1,2-diphenylethane-1-one, benzophenone, 2,4-dichlorobenzophenone, o-methyl benzoyl benzoate, 4,4′-bis(dimethylamino)benzophenone, and 4-benzoyl-4′-methyldiphenylsulfide, and anthracene compounds such as 9,10-diethoxyanthracene, 9,10-dibutoxyanthracene, and 9,10-bis(octanoyloxy)anthracene.

The leveling agent is a compound for improving the flatness of the coating film of the composition. Examples of the leveling agent include silicone-based, acrylic-based, and fluorine-based compounds. Examples of commercially available leveling agents include BYK-340 and BYK-345 (both manufactured by BYK Japan KK), and SURFLON S-611 (manufactured by AGC SEIMI CHEMICAL CO., LTD.).

The total content of the additional components (E) is preferably 20% by mass or less, more preferably 10% by mass or less, based on the total amount of the composition, from the viewpoint of reducing the low molecular weight components and reducing the damage to the device.

Physical Properties of Composition

Viscosity

As described above, the viscosity of the composition of the present invention measured by using an E-type viscometer at 25° C. and 20 rpm is 5 to 50 mPa·s, preferably 5 to 30 mPa·s, and more preferably 10 to 20 mPa·s. A viscosity in the above ranges is more likely to improve the ejection property during the application of the composition by the inkjet method.

Chloride Ion Concentration

The chloride ion content of the composition of the present invention is preferably 1,000 ppm or less, more preferably 500 ppm or less, even more preferably 300 ppm or less. When the concentration of chloride ions in the composition is high, the chloride ions may migrate from the cured product of the composition, which may cause corrosion of metal wiring or the like. When the chloride ion concentration is 1,000 ppm or less, ion migration is less likely to occur over a long period of time in the semiconductor device that includes the cured product of the composition, thereby minimizing the corrosion of metal wiring and the like.

The concentration of the chloride ions in the composition can be determined as follows. The composition is collected in a pressure-resistant container made of polytetrafluoroethylene (PTFE) and weighed, then 10 mL of pure water is added, and the container was sealed tightly. Then, chlorine is heat extracted in an oven at 100° C. (set temperature) for 20 hours. Then, after allowing to cool to room temperature, the extract is recovered and quantitative analysis of chloride ions is carried out by an ion chromatograph method (1C method).

The chloride ion concentration can be reduced, for example, by increasing the proportion of the epoxy compound having a cycloalkene oxide structure in the cationic polymerizable composition (A). Common epoxy compounds require, during the polymerization thereof, the use of materials that contain chlorine. Epoxy compounds having a cycloalkene oxide structure meanwhile do not require the use of materials that contain chlorine during the polymerization. The chloride ion concentration thus can be reduced by using a large amount of such a epoxy compound.

Surface Tension

The surface tension of the composition of the present invention is preferably 20 to 40 mN/m, more preferably 25 to 40 mN/m, and even more preferably 25 to 35 mN/m. Surface tension is a value measured by the Wilhelmy method at 25° C. Surface tension of the composition of 40 mN/m or less allows easier leveling during the application of the composition by the inkjet method, and thus the composition can evenly coat the circuit or the like of a semiconductor circuit board. On the other hand, when the surface tension of the composition is 20 mN/m or more, the composition is less likely to spread to wet the surface excessively during the application of the composition, thereby maintaining the desired thickness and pattern.

Oxygen Content

The oxygen content of the composition is preferably 15% or more, more preferably 20% or more, from the viewpoint of reducing damage to the inkjet device. On the other hand, the oxygen content of the composition is preferably 30% or less. The oxygen atom content of the composition can be calculated as follows: (Total mass of oxygen atoms contained in the composition/Total mass of the composition)×100(%). The total mass of oxygen atoms contained in the composition can be calculated by calculating the proportion of oxygen atoms contained in the composition by element analysis and multiplying the proportion by the atomic weight of oxygen atoms.

Method for Preparing Composition

The composition can be obtained by mixing at least the components (A) to (D) with a mixer such as a homodisper, a homomixer, a universal mixer, a planetary mixer, a kneader, or a three roll mixer.

1-2. Second Composition

The second composition contains an alicyclic epoxy compound (K), a photocationic polymerization initiator (L), and a silane coupling agent (M). The second composition has chloride ion content of 50 ppm or less, and a viscosity of 5 to 50 mPa·s measured at 25° C. and 20 rpm by using an E-type viscometer. The composition of the present invention has a very low chlorine ion concentration, thus is less likely to cause ion migration or the like even when the composition is used as, for example, a protective layer or an insulating layer of a semiconductor device. This composition has a sufficiently low viscosity, and thus can be applied by an inkjet method to form a film in a desired pattern.

The second composition also contains a silane coupling agent (M), and thus the cured product of the composition is more likely to adhere to various metal wiring, boards (substrates), and the like even at a high temperature. The second composition further contains a photocationic polymerization initiator (L), and thus the composition can be quickly cured by light and can maintain a desired shape. Therefore, the composition is particularly advantageous for forming a protective layer or an insulating layer that can sufficiently protect the wiring of a semiconductor circuit or the like for a long period of time. In the following, the composition of the present invention will be described in detail.

(K) Alicyclic Epoxy Compound

The alicyclic epoxy compound (K) is a compound that has two or more epoxy groups per molecule, and has an alicyclic structure. The alicyclic epoxy compound (K) is preferably a compound that is liquid at room temperature. The amount of the alicyclic epoxy compound (K) is preferably 30 to 99 parts by mass, more preferably 50 to 99 parts by mass, and even more preferably 80 to 99 parts by mass, based on 100 parts by mass of the total amount of the composition.

The composition may contain only one type of alicyclic epoxy compound (K), or two or more types of alicyclic epoxy compound (K). The number of epoxy groups contained in the alicyclic epoxy compound (K) is preferably 2 or more, more preferably 2 to 4, per molecule.

Examples of the alicyclic epoxy compound (K) include compounds having a cycloalkene oxide structure represented by the general formula below. A cycloalkene oxide structure is obtained by epoxidizing a cycloalkene with an oxidizing agent such as a peroxide. The structure has an aliphatic ring and an epoxy group composed of an oxygen atom and two carbon atoms that are part of the aliphatic ring.

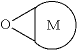

In the above general formula, M represents an alicyclic structure, and the number of carbon atoms of the alicyclic structure is preferably 4 to 8, more preferably 5 to 6. When the number of carbon atoms in the alicyclic structure of the cycloalkene oxide structure is in these ranges, the viscosity of the composition is more likely to become low.

In general, the use of a compound that contains chlorine is not necessary for synthesizing the alicyclic epoxy compound (K) having a cycloalkene oxide structure. The alicyclic epoxy compound (K) is thus less likely to contain chlorine ions; therefore, the concentration of chloride ions in the composition is more likely to fall within the above range.

Specific examples of the cycloalkene oxide structure include cyclohexene oxide and cyclopentene oxide, and cyclohexene oxide is preferred.

The number of cycloalkene oxide structures in one molecule of the alicyclic epoxy compound may be one (monofunctional) or two or more (polyfunctional). In particular, the number of cycloalkene oxide structures in one molecule of the alicyclic epoxy compound is preferably two or more (polyfunctional) from the viewpoint that the oxygen atom content described below can be easily increased and an excellent heat resistance can also be provided.

Examples of the alicyclic epoxy compound having a cycloalkene oxide structure include compounds represented by the general formulas (K-1) to (K-3) below.

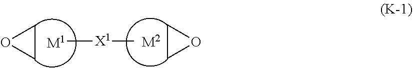

M¹ and M² in the general formula (K-1) each represent an alicyclic structure, and as described above, the number of carbon atoms of the alicyclic structure is preferably 4 to 8, more preferably 5 to 6. X¹ in the general formula (K-1) is a single bond or a linking group. The linking group is preferably selected in such a way that the weight average molecular weight and the oxygen atom content of the compound represented by the formula (K-1) fall within the ranges described below. Examples of the linking group include divalent hydrocarbon groups, carbonyl group, ether group (ether bond), thioether group (thioether bond), ester group (ester bond), carbonate group (carbonate bond), amide group (amide bond), and groups each having a plurality of these groups linked to each other.

Examples of the divalent hydrocarbon groups include alkylene groups having 1 to 18 carbon atoms or divalent alicyclic hydrocarbon groups. Examples of the alkylene groups having 1 to 18 carbon atoms include methylene group, methylmethylene group, dimethylmethylene group, ethylene group, propylene group and trimethylene group. Examples of the divalent alicyclic hydrocarbon groups include divalent cycloalkylene groups (including cycloalkylidene groups), such as 1,2-cyclopentylene group, 1,3-cyclopentylene group, cyclopentylidene group, 1,2-cyclohexylene group and 1,3-cyclohexylene group, 1,4-cyclohexylene group, and cyclohexylidene group.

In particular, X¹ is preferably a single bond or a linking group having an oxygen atom. More preferable linking groups having an oxygen atom are —CO— (carbonyl group), —O—CO—O— (carbonate group), —COO— (ester group), —O— (ether group), —CONH— (amide group), groups each having a plurality of these groups linked to each other, or groups each having one or more of these groups linked to one or more of the divalent hydrocarbon groups.

Examples of the alicyclic epoxy compound represented by the general formula (K-1) include the alicyclic epoxy compounds exemplified for the cationic polymerizable compound of the first composition described above.

The alicyclic epoxy compound (K) having a cycloalkene oxide structure may also be a compound having a structure represented by, for example, the following general formula (K-2) or (K-3).

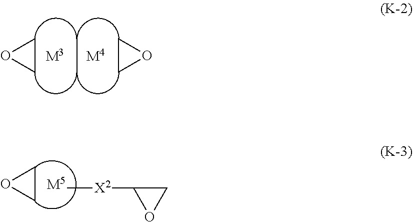

M³, M⁴ and M⁵ in the general formulas (K-2) and (K-3) each represent an alicyclic structure, and the number of carbon atoms of the alicyclic structure is preferably 4 to 8, more preferably 5 to 6. X² in the general formula (K-3) is a single bond or a linking group. The linking group is preferably selected in such a way that the weight average molecular weight and the oxygen atom content of the compound represented by the formula (K-3) fall within the ranges described below. The linking group is the same as the linking group in the above general formula (K-1). The compounds represented by the general formulas (K-2) and (K-3) may have an alkyl group or the like bonded to carbon of the alicyclic structure or of the epoxy group.

Examples of the alicyclic epoxy compound (K) represented by the general formula (K-2) or (K-3) include 3,4:7,8-diepoxybicyclo[4.3.0]nonane and limonene dioxide. Examples of commercially available products of the alicyclic epoxy compound (K) include THI-DE (manufactured by JX-TG) and LDO (manufactured by Nagase ChemteX Corporation).

For any of the above described alicyclic epoxy compounds (K), the weight average molecular weight thereof is preferably 180 or more, more preferably 190 or more, and even more preferably 200 or more. The upper limit of the weight average molecular weight of the alicyclic epoxy compound is appropriately selected according to the viscosity of the composition, but is preferably 400 or less. A weight average molecular weight of the alicyclic epoxy compound (K) of 180 or more can minimize volatilization of the alicyclic epoxy compound (K) from the composition. As a result, during the application of the composition by the inkjet method, the component amount in the composition is less likely to change, and the working environment is less likely to be impaired. The weight average molecular weight can be measured in terms of polystyrene by gel permeation chromatography (GPC).

The oxygen atom content (represented by the equation (2) below) of the alicyclic epoxy compound (K) is preferably 15% or more, more preferably 20% or more. On the other hand, the oxygen atom content is preferably 30% or less.

Oxygen atom content (%)=Total mass of oxygen atoms in one molecule/Weight average molecular weight×100 Equation (2)

When the oxygen atom content of the alicyclic epoxy compound (K) is 15% or more, the polarity of the alicyclic epoxy compound (K) increases, lowering the affinity with an adhesive and a rubber material (such as ethylene propylene butadiene rubber) which have a low polarity and are used in the head portion of the inkjet device. As a result, the adhesive and rubber material are less likely to swell, and their degradation (damage to the device) is less likely to occur.

The total mass of oxygen atoms in one molecule of the alicyclic epoxy compound (K) can be calculated by specifying the structure of the alicyclic epoxy compound (K) by GC-MS, NMR, or other methods, specifying the number of oxygen atoms in one molecule of the compound, and then multiplying the number by the atomic weight of an oxygen atom. The oxygen atom content of the alicyclic epoxy compound (K) can be calculated by applying the obtained total mass of oxygen atoms and the weight average molecular weight measured by the GPC method to the above equation (2). The oxygen atom content of the alicyclic epoxy compound (K) can be adjusted by the number of epoxy groups per molecule and the number of groups containing oxygen atoms.

(L) Photocationic Polymerization Initiator

The photocationic polymerization initiator (L) may be any compound that generates active species capable of initiating cationic polymerization by irradiation with an active light such as ultraviolet light. The amount of the photocationic polymerization initiator (L) contained in the composition is preferably 0.1 to 10 parts by mass, more preferably 0.1 to 5 parts by mass, based on 100 parts by mass of the alicyclic epoxy compound (K).

Examples of the photocationic polymerization initiator include aromatic sulfonium salts, aromatic iodonium salts, aromatic diazonium salts, and aromatic ammonium salts. The anion moiety of the salts is preferably BF₄—, PX₆— (X is a fluorine atom or a fluoroalkyl group), SbF₆—, or BX₄— (X is a phenyl group substituted with at least two or more fluorine atoms or a trifluoromethyl group). The composition may contain only one type of photocationic polymerization initiator (L), or two or more types of photocationic polymerization initiator (L).

Specific examples of the photocationic polymerization initiator (L) may be the same as those of the photocationic polymerization initiator (C) contained in the above first composition.

(M) Silane Coupling Agent

The silane coupling agent (M) is a compound having silane, and having a function of improving the adhesiveness of the cured product of the composition to the metal wiring or the board of a semiconductor device. The amount of the silane coupling agent (M) contained in the composition is preferably 1 to 50 parts by mass, more preferably 1 to 25 parts by mass, based on 100 parts by mass of the alicyclic epoxy compound (K).

Examples of the silane coupling agent (M) include silane compounds having a reactive group such as an epoxy group, a carboxyl group, a methacryloyl group, and an isocyanate group. More specific examples of the silane coupling agent (M) include trimethoxysilyl benzoate benzoic acid, γ-methacryloxypropyltrimethoxysilane, vinyltriacetoxysilane, vinyltrimethoxysilane, γ-isocyanatopropyltriethoxysilane, γ-glycidoxypropyltrimethoxysilane, and β-(3,4-epoxycyclohexyl)ethyltrimethoxysilane. The composition may contain only one type of silane compound (M), or two or more types of silane compound (M).

The silane coupling agent (M) may include a relatively high molecular weight compound (hereinafter referred to as a “high molecular weight silane coupling agent”) which has a Si—O—Si skeleton, an alkoxy group, and an epoxy group in one molecule thereof, and has a weight average molecular weight of 1,000 or more. The weight average molecular weight of the high molecular weight silane coupling agent is more preferably 1,000 to 5,000, even more preferably 1,500 to 2,500. When the silane coupling agent has a siloxane skeleton (Si—O—Si skeleton) and has a weight average molecular weight of 1,000 or more, the silane coupling agent (M) is more likely to be unevenly distributed on the surface of the metal wiring and the like of a semiconductor device, and the adhesion of the cured product of the composition to the metal wiring and the like of the semiconductor device is more likely to improve even in a high temperature and high humidity environment. A silane coupling agent (M) having an epoxy group is more likely to form a network with the alicyclic epoxy compound (K), and less likely to emerge from the cured product. A silane coupling agent having a weight average molecular weight of 5,000 or less is more likely to allow the viscosity of the composition to fall within a desired range. The weight average molecular weight of the silane coupling agent can be measured in terms of polystyrene by gel permeation chromatography (GPC).

The high molecular weight silane coupling agent may be the same as the silane coupling agent (B) of the above-described first composition.

(N) Additional Components

The composition of the present invention may additionally contain component(s) other than the alicyclic epoxy compound (K), the photocationic polymerization initiator (L), and the silane coupling agent (M) as long as the effects of the present invention are not impaired. Examples of the additional components include oxetane compounds, epoxy compounds other than the alicyclic epoxy compound (K), thermalcationic polymerization initiators, sensitizers, and leveling agents.

The oxetane compound is preferably a compound having one or more oxetane groups in one molecule thereof, and preferably a compound that is liquid at room temperature. The oxetane compound has a viscosity of preferably 1 to 500 mPa·s, more preferably 1 to 300 mPa·s, measured at 25° C. and 20 rpm by using an E-type viscometer. An oxetane compound having a viscosity in the above range is more likely to allow the viscosity of the composition to fall within a desired range and allow for stable application of the composition by the inkjet method.

An oxetane compound having a weight average molecular weight of 180 or more is less likely to volatilize in the inkjet device, thereby allowing stable application. The weight average molecular weight of the oxetane compound is preferably 190 or more, more preferably 200 or more, from the viewpoint of minimizing the volatilization of the oxetane compound. The upper limit of the weight average molecular weight of the oxetane compound may be any value as long as the ejection property of the composition is not impaired during the application of the compound by the inkjet method, and is preferably 400 or less, for example. The weight average molecular weight can be measured in the same manner as in the alicyclic epoxy compound (K).

The oxygen atom content of the oxetane compound is preferably 15% or more, more preferably 20% or more. On the other hand, the oxygen atom content is preferably 30% or less. When the oxygen atom content is high, the polarity of the oxetane compound increases, lowering the affinity with an adhesive and a rubber material (such as ethylene propylene butadiene rubber) which have a low polarity and are used in the head portion of the inkjet device. As a result, the adhesive and rubber material are less likely to swell, and their degradation (damage to the device) is less likely to occur. The oxygen atom content of the oxetane compound is defined in the same manner as in the alicyclic epoxy compound (K), and also the method for measuring the oxygen atom content can be the same as in the alicyclic epoxy compound (K).

The oxygen atom content of the oxetane compound can be adjusted by, for example, the number of oxetanyl groups per molecule of the oxetane compound, or the number of oxygen atoms in a group(s) bonded to the oxetanyl group.

The oxetane compound is preferably a compound represented by the general formula (N-1) or (N-2) below. The composition may contain only one type of oxetane compound, or two or more types of oxetane compound.

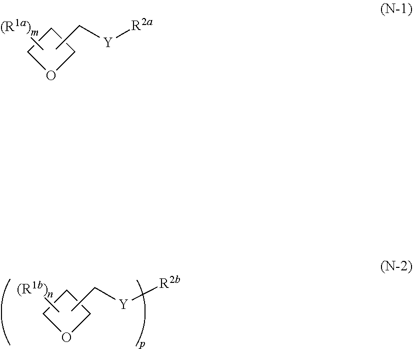

In the general formulas (N-1) and (N-2), Y represents an oxygen atom, a sulfur atom, or a single bond. In particular, an oxygen atom is preferred.

R^{1a} and R^{1b} each represent a fluorine atom, an alkyl group having 1 to 6 carbon atoms, a fluoroalkyl group having 1 to 6 carbon atoms, an allyl group, an aryl group having 6 to 18 carbon atoms, a furyl group or a thienyl group. Each of m and n represents an integer of 1 or more and 5 or less. When a plurality of R^{1a}a's or R^{1b}'s are contained in one molecule, they may be the same or different. Further, adjacent R^{1a}'s or adjacent R^{1b}'s may form a ring structure.

R^{2a} in the general formula (N-1) represents a hydrogen atom, an alkyl group having 1 to 10 carbon atoms, an alkenyl group having 2 to 6 carbon atoms, an aralkyl group having 7 to 18 carbon atoms, an alkylcarbonyl group having 2 to 6 carbon atoms, an alkoxycarbonyl group having 2 to 6 carbon atoms, an N-alkylcarbamoyl group having 2 to 6 carbon atoms, or a (meth)acryloyl group.

R^{2b} in the general formula (N-2) represents a p-valent linking group, where p represents 2, 3, or 4. R^{2b} represents, for example, a linear or branched alkylene group having 1 to 12 carbon atoms, a linear or branched poly(alkyleneoxy) group, an arylene group, a siloxane bond, or a combination thereof.

R^{1a}, R^{1b}, R^{2a}, and R^{2b} in the general formulas (N-1) and (N-2) are preferably selected in such a way that the weight average molecular weight and the oxygen atom content fall within the above ranges.

From the viewpoint of obtaining and an appropriate viscosity of the composition, the oxetane compound represented by the following general formula (N-3) is preferred.

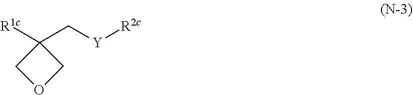

Y in the general formula (N-3) is an oxygen atom or a sulfur atom. R^{1c} represents a hydrogen atom, a fluorine atom, an alkyl group having 1 to 6 carbon atoms, a fluoroalkyl group having 1 to 6 carbon atoms, an aryl group having 6 to 18 carbon atoms, a furyl group or a thienyl group. In particular, an alkyl group having 1 to 6 carbon atoms is preferred from the viewpoint of reducing the viscosity of the composition.

R^{2c} is a hydrogen atom, an alkyl group having 1 to 10 carbon atoms, an alkenyl group having 2 to 6 carbon atoms, an aralkyl group having 7 to 18 carbon atoms, an alkylcarbonyl group having 2 to 6 carbon atoms, an alkoxycarbonyl group having 2 to 6 carbon atoms, an N-alkylcarbamoyl group having 2 to 6 carbon atoms, or a (meth)acryloyl group. In particular, an alkyl group having 1 to 10 carbon atoms is more preferred from the viewpoint of reducing the viscosity of the composition.

Examples of the compound represented by the general formula (N-3) include 3-ethyl-3-hydroxymethyloxetane, 3-(meth)allyloxymethyl-3-ethyloxetane, (3-ethyl-3-oxetanylmethoxy)methylbenzene, 4-fluoro-[1-(3-ethyl-3-oxetanylmethoxy)methyl]benzene, 4-methoxy-[1-(3-ethyl-3-oxetanylmethoxy)methyl]benzene, [1-(3-ethyl-3-oxetanylmethoxy)ethyl]phenylether, isobutoxymethyl(3-ethyl-3-oxetanylmethyl)ether, isobornyloxyethyl(3-ethyl-3-oxetanylmethyl)ether, isobornyl(3-ethyl-3-oxetanylmethyl)ether, 2-ethylhexyl(3-ethyl-3-oxetanylmethyl)ether, ethyldiethyleneglycol(3-ethyl-3-oxetanylmethyl)ether, dicyclopentadiene(3-ethyl-3-oxetanylmethyl)ether, 3-methyloxymethyl-3-ethyloxetane, and 3-ethyl-3-[(2-ethylhexyloxy)methyl]oxetane. In particular, 3-ethyl-3-[(2-ethylhexyloxy)methyl]oxetane is preferred.

Examples of commercially available oxetane compounds include OXT-221, OXT-121, and OXT-212 (all manufactured by Toagosei Co., Ltd.), OXBP and HBOX (both manufactured by Ube Industries, Ltd.).

The amount of the oxetane compound is preferably 40 parts by mass or less, more preferably 25 parts by mass or less, based on 100 parts by mass of the total amount of the composition. The presence of the oxetane compound is more likely to allow the viscosity of the composition to fall within a desired range. When the amount of oxetane compound is 40 parts by mass or less, for example, the amount the alicyclic epoxy compound (K) relatively increases, and thus the strength of the cured product of the composition is more likely to increase.

Examples of epoxy compounds other than the alicyclic epoxy compound (K) include aliphatic epoxy compounds and aromatic epoxy compounds. The aliphatic epoxy compounds and the aromatic epoxy compounds are each preferably a compound having two or more epoxy groups in one molecule thereof, and preferably a compound that is liquid at room temperature. The weight average molecular weight of each of the aliphatic epoxy compound and the aromatic epoxy compound is preferably 180 or more, more preferably 190 or more, even more preferably 200 or more. An aliphatic epoxy compound or an aromatic epoxy compound having a weight average molecular weight within the above ranges is less likely to volatilize in the inkjet device, thereby allowing stable application. The upper limit of the weight average molecular weight of the epoxy compound may be any value as long as the ejection property is not impaired during the application of the composition by the inkjet method, and is preferably 400 or less, for example. The weight average molecular weight of the epoxy compound can be measured in the same manner as in the alicyclic epoxy compound (K).

The oxygen atom content of each of the aliphatic epoxy compound and the aromatic epoxy compound is preferably 15% or more, more preferably 20% or more. On the other hand, the oxygen atom content is preferably 30% or less. An oxygen atom content of the aliphatic epoxy compound or the aromatic epoxy compound in the range lowers the affinity with an adhesive and a rubber material (such as ethylene propylene butadiene rubber) which have a low polarity and are used in the head portion of the inkjet device. The oxygen atom content of the aliphatic epoxy compound and the aromatic epoxy compound is defined in the same manner as in the alicyclic epoxy compound (K), and also the method for measuring the oxygen atom content can be the same as in the alicyclic epoxy compound (K).

A known compound can be used as the aliphatic epoxy compound or the aromatic epoxy compound, and the epoxy compound may have any structure. The amount of the aliphatic epoxy compound and the aromatic epoxy compound is preferably small from the viewpoint of reducing the chloride ion content in the composition, and is preferably 20 parts by mass or less, more preferably 10 parts by mass or less, based on 100 parts by mass of the total amount of the composition.

The thermalcationic polymerization initiator may be any compound that generates active species capable of initiating cationic polymerization by heating. Examples of the thermalcationic polymerization initiator include known cationic polymerization initiators. Examples of the thermalcationic polymerization initiator include the same compounds as the examples of the thermalcationic polymerization initiator (D) contained in the first composition as described above. The composition may contain only one type of thermalcationic polymerization initiator, or two or more types of thermalcationic polymerization initiator. The amount of the thermalcationic polymerization initiator is preferably 10 parts by mass or less, more preferably 5 parts by mass or less, based on 100 parts by mass of the total amount of the composition.

The sensitizer is a compound having a function of further improving the efficiency of generating active species of the photocationic polymerization initiator (L) and the thermalcationic polymerization initiator to further promote the curing reaction of the composition. Examples of the sensitizers include thioxanthone compounds such as 2,4-diethylthioxanthone, benzophenone compounds such as 2,2-dimethoxy-1,2-diphenylethane-1-one, benzophenone, 2,4-dichlorobenzophenone, o-methyl benzoyl benzoate, 4,4′-bis(dimethylamino)benzophenone, and 4-benzoyl-4′-methyldiphenylsulfide; and anthracene compounds such as 9,10-diethoxyanthracene, 9,10-dibutoxyanthracene, and 9,10-bis(octanoyloxy)anthracene.

The leveling agent is a compound for improving the flatness of the coating film of the composition. Examples of the leveling agent include silicone-based, acrylic-based, and fluorine-based compounds. Examples of commercially available leveling agents include BYK-340 and BYK-345 (both manufactured by BYK Japan KK), and SURFLON S-611 (manufactured by AGC SEIMI CHEMICAL CO., LTD.).

The total content of the sensitizer and the leveling agent is preferably 20% by mass or less, more preferably 10% by mass or less, based on the total amount of the composition, from the viewpoint of reducing the low molecular weight components and reducing the damage to the device.

Physical Properties of Composition

Viscosity

As described above, the viscosity of the second composition measured by using an E-type viscometer at 25° C. and 20 rpm is 5 to 50 mPa·s, preferably 5 to 30 mPa·s, and more preferably 10 to 20 mPa·s. A viscosity in the above ranges is more likely to improve the ejection property during the application of the composition by the inkjet method.

Chloride Ion Concentration

The chloride ion content of the second composition is 50 ppm or less, preferably 30 ppm or less, and more preferably 10 ppm or less. When the chloride ion concentration is 50 ppm or less, ion migration is less likely to occur over a long period of time in the semiconductor device that includes the cured product of the composition, thereby minimizing the corrosion of a semiconductor device. The concentration of the chloride ions in the composition can be determined as follows. The composition is collected in a pressure-resistant container made of polytetrafluoroethylene (PTFE) and weighed, then 10 mL of pure water is added, and the container was sealed tightly. Then, chlorine is heat extracted in an oven at 100° C. (set temperature) for 20 hours. Then, after allowing to cool to room temperature, the extract is recovered and quantitative analysis of chloride ions is carried out by an ion chromatograph method (1C method).

Surface Tension

The surface tension of the second composition is preferably 20 to 40 mN/m, more preferably 25 to 40 mN/m, and even more preferably 25 to 35 mN/m. Surface tension is a value measured by the Wilhelmy method at 25° C. Surface tension of the composition of 40 mN/m or less allows easier leveling during the application of the composition by the inkjet method, and thus the composition can evenly coat the circuit or the like of a semiconductor circuit board. On the other hand, when the surface tension of the composition is 20 mN/m or more, the composition is less likely to spread to wet the surface excessively during the application of the composition, thereby maintaining the desired thickness and pattern.

Oxygen Content

The oxygen content of the second composition is preferably 15% or more, more preferably 20% or more, from the viewpoint of reducing damage to the inkjet device. On the other hand, the oxygen content of the composition is preferably 30% or less. The oxygen atom content of the composition can be calculated as follows: (Total mass of oxygen atoms contained in the composition/Total mass of the composition)×100(%). The total mass of oxygen atoms contained in the composition can be calculated by calculating the proportion of oxygen atoms contained in the composition by element analysis and multiplying the proportion by the atomic weight of oxygen atoms.

Physical Properties of Cured Product

The loss tangent (tan δ) of the cured product of the second composition at 25° C. to 150° C., obtained by dynamic viscoelasticity measurement at a frequency of 1.6 Hz (10 rad/s), is preferably 0.01 or more, more preferably 0.03 or more, and even more preferably 0.05 or more. The above values are determined by the measurement after irradiating the composition with light having a wavelength of 395 nm at 450 mJ/cm² and further curing the composition at 23° C. for 30 minutes. When the loss tangent (tan δ) of the cured product is within the ranges, ion migration is less likely to occur.

The storage elastic modulus E′ of the cured product at 85° C., obtained by dynamic viscoelasticity measurement at a frequency of 1.6 Hz (10 rad/s), is preferably 1×10⁶ Pa to 1×10¹⁰ Pa, and more preferably 1×10⁷ Pa to 1×10¹⁰ Pa. The loss tangent (tan δ) under this condition is preferably 0.03 or more, and more preferably 0.05 or more.

When a cured product whose storage elastic modulus and the loss tangent at 85° C. are within the above ranges is used for a repassivation layer or the like of a semiconductor device, the repassivation layer or the like is more likely to sufficiently absorb the impact even in a high temperature environment.

In addition, the peak of the loss tangent (tan δ) of the cured product, obtained by dynamic viscoelasticity measurement at a frequency of 1.6 Hz (10 rad/s), is in the range of preferably 50° C. to 200° C., more preferably 100° C. to 200° C., and even more preferably 120 to 200° C. When the peak of the loss tangent is within the above ranges, ion migration is less likely to occur.

The viscosity measured at 25° C. and 20 rpm by using an E-type viscometer after irradiating the above composition with light having a wavelength of 395 nm at 23° C. and 450 mW/cm² is preferably 50 mPa·s or more, more preferably 70 mPa·s or more. When the viscosity after irradiation with light is within the above ranges, the shape of the composition is less likely to change after irradiation with light, allowing a desired shape to be maintained.

Method for Preparing Composition

The composition can be obtained by mixing at least the components (K) to (M) with a mixer such as a homodisper, a homomixer, a universal mixer, a planetary mixer, a kneader, or a three roll mixer.

2. Semiconductor Device

The semiconductor device of the present invention can be configured in any way, as long as a part of the semiconductor device (for example, semiconductor circuit and copper wiring) is covered by the cured product (cured product layer) of the inkjet coating-type semiconductor protection composition described above. The semiconductor device may have any structure.

The semiconductor device may be a device (first embodiment) including, for example, the following: a semiconductor circuit board provided with a circuit disposed on at least one surface thereof; a cured product layer of an inkjet coating-type semiconductor protection composition—the cured product layer covers at least a part of the circuit of the semiconductor circuit board; and a semiconductor mold resin layer disposed on or above the cured product layer. Alternatively, the semiconductor device may be a device (second embodiment) including the following: a board (substrate) with metal wiring disposed thereon; a cured product layer of an inkjet coating-type semiconductor protection composition—the cured product layer covers at least a part of the board; and a circuit portion disposed on or above the cured layer so as to be electrically connected to the metal wiring. Hereinafter, each embodiment will be described.

### First Embodiment

The semiconductor device of the first embodiment includes at least a semiconductor circuit board, a cured product layer of an inkjet coating-type semiconductor protection composition, and a semiconductor mold resin layer, and may additionally include other components as necessary.

The semiconductor circuit board may be a board on which a desired circuit is formed on one surface or both surfaces of the board. For example, structures with various circuits (metal wiring) formed on various boards are possible. The type of the board is not particularly limited, and for example, a known board made of SiON, SiN, or SiO² may be used. Further, the material and pattern of the circuit (metal wiring) are not particularly limited, and a circuit made of a metal, such as copper, used in a common semiconductor device can be used.

The cured product layer of the inkjet coating-type semiconductor protection composition, which is disposed on the semiconductor circuit board, is a layer obtained by applying and curing the inkjet coating-type semiconductor protection composition described above. When the circuit is formed on either side of the semiconductor circuit board, the cured product layer may be formed on either side. The cured product layer may, for example, function as an insulating layer to prevent electrical conduction between the circuit and other members, or may function as a protective layer to prevent corrosion or breakage of the circuit. In particular, forming a cured product layer between the semiconductor circuit board and the mold resin allows the cured product layer to serve as a cushion to protect the circuit from impact.

The shape of the cured product layer is appropriately selected according to the type and application of the semiconductor device. For example, the cured product layer may cover the entire circuit formed on the semiconductor circuit board, or may cover only a part of the circuit.

The thickness of the cured product layer is not particularly limited as long as the cured product layer can sufficiently protect or insulate the circuit on the semiconductor circuit board. For example, the thickness is preferably 5 to 20 μm, more preferably 5 to 10 μm.

The semiconductor mold resin layer is a layer disposed on or above the cured product layer, and the shape of the layer is appropriately selected according to the type and application of the semiconductor device. The semiconductor mold resin layer may be disposed in a pattern on the cured product layer, or may be disposed so as to cover the entire surface of the cured product layer. A known mold resin layer of a semiconductor device can serve as the semiconductor mold resin layer.

The semiconductor device of the present embodiment can be produced by various method, such as a method including the following steps: 1) preparing a semiconductor circuit board that includes a circuit formed on at least one surface of the semiconductor circuit board; 2) applying the inkjet coating-type semiconductor protection composition on the semiconductor circuit board by an inkjet method; 3) photo curing of curing a coating film of the inkjet coating-type semiconductor protection composition by irradiating the coating film with active light within 60 seconds after the applying step; and 4) thermal curing of curing the coating film after the photo curing step with heat. The method may further include a step of forming a semiconductor mold resin layer, as necessary.

The preparing step 1) is a step of preparing the above-described semiconductor circuit board, and may be, for example, a step of forming a circuit on any one of various boards by a known method (for example, a sputtering method).

The applying step 2) is a step of applying an inkjet coating-type semiconductor protection composition on a semiconductor circuit board by an inkjet method. The inkjet device that can be used for applying the inkjet coating-type semiconductor protection composition may be a known device including an ink tank, an inkjet recording head, a drive mechanism for the inkjet recording head, and the like. The type of the inkjet recording head is not particularly limited, and for example, either a piezo type or a valve type may be used. The conditions during the application are not limited and appropriately selected according to the thickness and pattern of the cured product layer.

The photo curing step 3) is a step of curing a coating film of the inkjet coating-type semiconductor protection composition by irradiating the coating film with active light within 60 seconds from the end the applying step. The photo curing step is preferably performed within 10 seconds from the end of the applying step. The type of active light used in the photo curing step is not particularly limited and is appropriately selected according to the type of photocationic polymerization initiator contained in the above-described composition, but ultraviolet light is usually used. The light source used for irradiation is also not particularly limited, and examples thereof include known light sources such as xenon lamps, carbon arc lamps, and UV-LED light sources.

The irradiation amount of the active light may be any amount as long as the shape of the inkjet coating-type semiconductor protection composition does not change due to the irradiation with the active light. For example, when light having a wavelength of 300 to 400 nm is used, setting the integrated light amount to 300 to 3,000 mJ/m² cures the coating film of the inkjet coating-type semiconductor protection composition.

The thermal curing step 4) is a step of further curing the coating film with heat after the photo curing step. Performing the thermal curing step can sufficiently cure the coating film of the inkjet coating-type semiconductor protection composition. The heating temperature is preferably 80 to 180° C., more preferably 100 to 150° C. The heating time is preferably 10 to 60 minutes, more preferably 10 to 30 minutes.

### Second Embodiment

The semiconductor device of the second embodiment includes at least a board with metal wiring disposed thereon, a cured product of an inkjet coating-type semiconductor protection composition, and a circuit portion, and may additionally include other components as necessary. Various circuits are typically disposed on the board with metal wiring disposed thereon. In the present embodiment, the metal wiring may be disposed on only one surface of such a board, or the metal wiring may be disposed on the both surfaces. The pattern of the metal wiring is appropriately selected according to the type and application of the semiconductor device.

The cured product layer of the inkjet coating-type semiconductor protection composition—the cured product is disposed on or above the metal wiring—is a layer obtained by applying and curing the inkjet coating-type semiconductor protection composition described above. The cured product layer is a layer for protecting the metal wiring or the like from impact or the like, and is a layer that functions as a so-called repassivation layer or the like. The shape of the cured product layer is appropriately selected according to the type and application of the semiconductor device, and may have a through hole or the like for electrically connecting the metal wiring and the electrode.

The thickness of the cured product layer may be any thickness that can protect or insulate the metal wiring, and is preferably 5 to 20 μm, more preferably 5 to 10 μm, for example.

The structure and type of the circuit portion disposed on the cured product layer are appropriately selected according to the type and application of the semiconductor device. For example, the circuit portion may be one of various circuits or the like, which is disposed on the metal wiring exposed in the region where the cured product layer is not formed.

The semiconductor device of the present embodiment can be produced by various method, such as a method including the following steps: 1) preparing a board with metal wiring on at least one surface thereof; 2) applying the inkjet coating-type semiconductor protection composition on the metal wiring of the board by an inkjet method; 3) photo curing of curing a coating film of the inkjet coating-type semiconductor protection composition by irradiating the coating film with active light within 60 seconds after the applying step; and 4) thermal curing of curing the coating film after the photo curing step with heat. The method may further include a step of forming a circuit portion, as necessary.

The preparing step 1) is a step of preparing a board including metal wiring, and may be, for example, a step of forming metal wiring on a semiconductor circuit board by a known method.

The applying step 2) is a step of applying an inkjet coating-type semiconductor protection composition on the metal wiring of the board by an inkjet method. The inkjet device used for applying the inkjet coating-type semiconductor protection composition is the same as the inkjet device used in the first embodiment. The application conditions of the inkjet coating-type semiconductor protection composition are not particularly limited, and are appropriately selected according to the thickness and pattern of the cured product layer.

The photo curing step 3) is a step of curing a coating film of the inkjet coating-type semiconductor protection composition by irradiating the coating film with active light within 60 seconds from the end the applying step. The photo curing step is preferably performed within 10 seconds from the end of the applying step. The type of active light is not particularly limited and is appropriately selected according to the type of photocationic polymerization initiator contained in the above-described composition, but ultraviolet light is usually used. Examples of the light source used for irradiation include known light sources such as xenon lamps, carbon arc lamps, and UV-LED light sources. The irradiation with the active light may be performed in any method as long as the shape of the inkjet coating-type semiconductor protection composition does not change due to the irradiation with the active light. For example, irradiating with light having a wavelength of 300 to 400 nm at the integrated light amount of 300 to 3,000 mJ/m² sufficiently cures the coating film.

The thermal curing step 4) is a step of further curing the coating film with heat after the photo curing step. Performing the thermal curing step can sufficiently cure the coating film of the inkjet coating-type semiconductor protection composition. The heating temperature is preferably 80 to 180° C., more preferably 100 to 150° C. The heating time is preferably 10 to 60 minutes, more preferably 10 to 30 minutes.

3. Semiconductor Protection Member

The present invention also provides a semiconductor protection member that contains a cured product described below. Specifically, the present invention provides a semiconductor protection member containing a cured product of an organic polymerizable compound having a functional group containing an oxygen atom and/or a nitrogen atom. The absolute value of the difference between the coefficient of linear expansion of the cured product at 150° C. and the coefficient of linear expansion of the cured product at 25° C. is 55 or less. When the absolute value of the difference in the coefficient of linear expansion is small, the semiconductor protection member is less likely to be affected by the temperature, and can stably protect a semiconductor for a long period of time. In addition, the total amount of anions detected when 0.25 g of the cured product is immersed in 10 mL of water at 100° C. and subjected to extraction for 20 hours is preferably 50 ppm or less.

The pH of water after 0.25 g of the cured product is immersed in 10 mL of the water at 100° C. and left for 20 hours is preferably 4.4 to 8.7. When the amount of anions detected when the cured product is immersed in water is equals to or less than the above value, or the pH is within the above range, ion migration is less likely to occur in the semiconductor protection member. The semiconductor protection member thus can stably protect a semiconductor for a long period of time.

In addition, the water absorption percentage of the cured product is preferably 2% or less. When the water absorption percentage of the cured product is within the above range, the semiconductor protection member is less likely to absorb moisture in the atmosphere, and can sufficiently protect a semiconductor.

Further, the semiconductor protection member preferably contains a Si—O bond in a part thereof, and more preferably contains a Si—O—Si skeleton. A semiconductor protection member containing Si—O—Si skeletons is more likely to improve the adhesion between the semiconductor protection member and the metal wiring and the like of the semiconductor device even in a high temperature and high humidity environment. The Si—O—Si skeleton preferably has a structure derived from a silane coupling agent, and more preferably a structure derived from a silane coupling agent having an average molecular weight of 1,000 or more. That is, the semiconductor protection member particularly preferably contains a cured product of a silane coupling having an average molecular weight of 1,000 or more.

The semiconductor protection member preferably contains a cured product of at least one organic polymerizable compound selected from the group consisting of epoxy compounds, urethane compounds, (meth)acrylic compounds, imide compounds, and benzoxazole. In particular, the cured product is preferably a cured product of the cationic polymerizable compound or the alicyclic epoxy compound contained in the above-described composition. That is, the semiconductor protection member of the present invention is preferably a cured product of the above-described inkjet coating-type semiconductor protection composition.

### EXAMPLES

The present invention will be described in detail based on examples, but the present invention is not limited to these examples.

1. First Composition

1-1. Material

(A) Cationic Polymerizable Compound
CEL8010 (manufactured by Daicel Corporation, Alicyclic compound, number of epoxy groups: 2)
EPOGOSEY NPG (D) (manufactured by Yokkaichi Chemical Company Limited, Neopentyl glycol diglycidyl ether, number of epoxy groups: 2)
OXT-221 (manufactured by Toagosei Co., Ltd., 3-Ethyl-3{[(3-ethyloxetane-3-yl)methoxy]methyl}oxetane, number of oxetane groups: 2)

THI-DE (manufactured by JX-TG, 3,4:7,8-Diepoxybicyclo[4.3.0]nonane represented by the following structural formula)

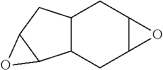 [SMILES: C1C2CC3OC3C2CC2OC12]

(B) Silane Coupling Agent
KR-516 (manufactured by Shin-Etsu Chemical Co., Ltd., Epoxy group-containing alkoxy oligomer, weight average molecular weight >1,000)
KR-517 (manufactured by Shin-Etsu Chemical Co., Ltd., Epoxy group-containing alkoxy oligomer, weight average molecular weight >1,000)
KBM-303 (manufactured by Shin-Etsu Chemical Co., Ltd., 2-(3,4-Epoxycyclohexyl)ethyltrimethoxysilane, weight average molecular weight <500)
KBM-403 (manufactured by Shin-Etsu Chemical Co., Ltd., 3-Glycidoxypropyltriethoxysilane, weight average molecular weight <500)

(C) Photocationic Polymerization Initiator
CPI-210S (manufactured by San-Apro Ltd.)

(D) Thermalcationic Polymerization Initiator
K-PURE CXC-1612 (manufactured by King Industries, Inc.)

1-2. Preparation of Inkjet Coating-type Semiconductor Protection Composition

### Example 1

A cationic polymerizable compound (A), a silane coupling agent (B), a photocationic polymerization initiator (C), and a thermalcationic polymerization initiator (D) at amounts shown in Table 1 were placed in a flask and mixed. The resulting mixture was stirred until no powder was visible to obtain an inkjet coating-type semiconductor protection composition.

### Examples 2 to 8 and Reference Examples 1 to 13

Each inkjet coating-type semiconductor protection composition was obtained in the same manner as in Example 1 except that the amounts of the components were changed so as to have the composition shown in Table 1 or Table 2.

Evaluation

The methods described below were used to evaluate the viscosity and patterning retention of the obtained inkjet coating-type semiconductor protection composition, adhesion of a semiconductor protection member obtained from the inkjet coating-type semiconductor protection composition after pressure cooker test (PCT), the difference between the coefficient of linear expansion of the semiconductor protection member at 150° C. and the coefficient of linear expansion of the semiconductor protection member at 25° C., the pH of water after the semiconductor protection member was immersed in the water for a certain period of time, and water absorption percentage of the semiconductor protection member. Tables 1 and 2 show the results.
Viscosity

The viscosity was measured at 25° C. and 20 rpm by using an E-type viscometer.
Patterning Retention

An ink tank of an inkjet device was filled with each inkjet coating-type semiconductor protection composition. The inkjet device was used to apply the inkjet coating-type semiconductor protection composition to a copper plate and to a 10 cm square SiON sputtered glass. The application pattern was a 5 cm square. The application was performed in such a way that the application amount was 7 pL/drop and the application interval between drops was 30 μm to have a film thickness of 10 μm.

Within 60 seconds after the inkjet coating-type semiconductor protection composition was applied, the obtained coating film was irradiated with ultraviolet light (wavelength: 365 nm, irradiation light amount: 1,000 mJ/cm²). The coating film was then heated at 150° C. for 30 minutes for thermally curing to form a film with a thickness of 10 μm. The shape of the cured film after the thermal curing was visually checked and evaluated as follows:

Good: The change of application pattern on each side after thermal curing was within ±5%.

Fair: The change of application pattern on each side after thermal curing was beyond ±5% and within ±10%.

Poor: The change of application pattern on each side after thermal curing was beyond ±10%.
Adhesion after Pressure Cooker Test (PCT)

An ink tank of an inkjet device was filled with each inkjet coating-type semiconductor protection composition. The inkjet device was used to apply the inkjet coating-type semiconductor protection composition to a copper plate and to SiON sputtered glass. The application pattern was a 5 cm square. The application was performed in such a way that the application amount was 7 pL/drop and the application interval between drops was 30 μm to have a film thickness of 10 μm.

Within 60 seconds after the inkjet coating-type semiconductor protection composition was applied, the obtained coating film was irradiated with ultraviolet light (wavelength: 365 nm, irradiation light amount: 1,000 mJ/cm²). The coating film was then heated at 150° C. for 30 minutes for thermally curing to form a film with a thickness of 10 μm.

The obtained test piece was stored in highly accelerated stress test system (EHS-222, manufactured by ULVAC, Inc.) at 121° C. and 100% Rh for 96 hours to perform the pressure cooker test (PCT). Then, a grid pattern peeling test (cross-cut test) was performed in accordance with ISO 2409, and the adhesion of the cured film was evaluated according to the following criteria:

Good: Number of remaining squares was 95 to 100/100.

Fair: Number of remaining squares was 50 to 94/100.

Poor: Number of remaining squares was 0 to 49/100.
Absolute Value of Difference Between Coefficients of Linear Expansion at 150° C. and Coefficient of Linear Expansion at 25° C. of Semiconductor Protection Member

A coating film of each inkjet coating-type semiconductor protection composition was formed on release paper by using an applicator. The thickness of the coating film was set to 100 μm. The coating film was irradiated with light having a wavelength of 395 nm at 450 mW/cm² and cured at 150° C. for 30 minutes. The obtained cured product was peeled off from the release paper, and the temperature-linear expansion coefficient was measured with TMA manufactured by Seiko Instruments Inc. From the measured values, the absolute value of the difference between the coefficient of linear expansion at 150° C. and the coefficient of linear expansion at 25° C. were calculated.
The pH of Water after Immersion of Semiconductor Protection Member (Cured Product) in Water for a Certain Period of Time

A cured product (semiconductor protection member) of the inkjet coating-type semiconductor protection composition was produced in the same manner as in the case of the measurement of the coefficient of linear expansion. First, 0.25 g of the cured product was weighed and placed in a PTFE pressure-resistant container, 10 mL of pure water was added, and the container was sealed tightly. Then, the pressure-resistant container was held in an oven at 100° C. (set temperature) for 20 hours. After allowing to cool to room temperature, the liquid was recovered and the pH was measured with a pH meter HM-30G manufactured by DKK-TOA CORPORATION.
Water Absorption Percentage of Semiconductor Protection Member (Cured Product)

A cured product (semiconductor protection member) of the inkjet coating-type semiconductor protection composition was produced in the same manner as in the case of the measurement of the coefficient of linear expansion. The cured product was then pre-dried at 150° C. for 12 hours, and the mass thereof was specified. Subsequently, the cured product was placed in an environment of 23° C. and 70% RH for 24 hours, and the mass of the cured product after moisture absorption was specified. The water absorption percentage was then determined from the change in the mass before and after the moisture absorption.

TABLE 1

| | | | Example | | | | Reference Example | | | | | | |
|---|---|---|---|---|---|---|---|---|---|---|---|---|---|
| | | | 1 | 2 | 3 | 4 | 1 | 2 | 3 | 4 | 5 | 6 | 7 |
| Compo- | Cationic polymerizable | CEL8010 | 20 | 20 | 20 | 20 | 20 | 20 | 20 | 20 | 20 | 20 | 60 |
| sition | compound (A) | NPG(D) | 24 | 24 | 24 | 24 | 24 | 24 | 24 | 24 | 24 | 24 | 5 |
| | | OXT-221 | 56 | 56 | 56 | 56 | 56 | 56 | 56 | 56 | 56 | 56 | 40 |
| | Silane coupling agent (B) | KBM-303 | | | | | | | | 2 | 10 | | |
| | | (MW* < 500) | | | | | | | | | | | |
| | | KBM-403 | | | | | | | | | | 2 | 2 |
| | | (MW < 500) | | | | | | | | | | | |
| | | KR-516 | 2 | 10 | | | | | | | | | |
| | | (MW > 1,000) | | | | | | | | | | | |
| | | KR-517 | | | 2 | 10 | | | | | | | |
| | | (MW > 1,000) | | | | | | | | | | | |
| | Photocationic | CPI-210S | 0.5 | 0.5 | 0.5 | 0.5 | 0.5 | 0.5 | | 0.5 | 0.5 | 0.5 | 0.5 |
| | polymerization | | | | | | | | | | | | |
| | initiator (C) | | | | | | | | | | | | |
| | Thermalcationic | CXC-1612 | 0.1 | 0.1 | 0.1 | 0.1 | 0.1 | | 0.1 | 0.1 | 0.1 | 0.1 | 0.1 |
| | polymerization initiator (D) | | | | | | | | | | | | |
| | (D)/(C)** × 100 | | 20 | 20 | 20 | 20 | 20 | — | 20 | 20 | 20 | 20 | 20 |
| Evalu- | Viscosity at 25° C. (mPa · s) | 25° C., 20 rpm | 14 | 13 | 16 | 18 | 14 | 14 | 14 | 14 | 13 | 14 | 18 |
| ation | Surface tension (mN/m) | | 25 to 35 | | | | | | | | | | |
| | Patterning retention | Change after 30 | Good | Good | Good | Good | Good | Poor | Poor | Good | Good | Good | Good |
| | | min at 150° C. | | | | | | | | | | | |
| | Adhesion after PCT | 121° C., 100% | Good | Good | Good | Good | Poor | Poor | Poor | Fair | Fair | Fair | Poor |
| | (cross-cut test) | RH, 96 hr | | | | | | | | | | | |

| | | | | | | | | | | | |
|---|---|---|---|---|---|---|---|---|---|---|---|
| Absolute value of difference in coefficient of | 39 | — | — | — | — | — | — | — | — | — | 59 |
| linear expansion between 150° C. and 25° C. | | | | | | | | | | | |
| pH of water after 0.25 g of cured product is | 4.9 | — | — | — | — | — | — | — | — | — | 5.2 |
| immersed in 10 mL of water at 100° C. and | | | | | | | | | | | |
| left for 20 hours | | | | | | | | | | | |
| Water absorption percentage of | 1.6 | — | — | — | — | — | — | — | — | — | 1.3 |
| cured product (%) | | | | | | | | | | | |

*MW: Molecular weight,
**(D)/(C): Thermalcationic polymerization initiator (D)/Photocationic polymerization initiator (C)

TABLE 2

| | | | Example | | | | Reference Example | | | | | |
|---|---|---|---|---|---|---|---|---|---|---|---|---|
| | | | 5 | 6 | 7 | 8 | 8 | 9 | 10 | 11 | 12 | 13 |
| Compo- | Cationic polymerizable | CEL8010 | 20 | 20 | 20 | 20 | 20 | 20 | 20 | 20 | 20 | 20 |
| sition | compound (A) | THI-DE | 24 | 24 | 24 | 24 | 24 | 24 | 24 | 24 | 24 | 24 |
| | | OXT-221 | 56 | 56 | 56 | 56 | 56 | 56 | 56 | 56 | 56 | 56 |
| | Silane coupling agent (B) | KBM-303 | | | | | | | | 2 | 10 | |
| | | (MW* < 500) | | | | | | | | | | 2 |
| | | KBM-403 | | | | | | | | | | |
| | | (MW < 500) | | | | | | | | | | |
| | | KR-516 | 2 | 10 | | | | | | | | |
| | | (MW > 1,000) | | | | | | | | | | |
| | | KR-517 | | | 2 | 10 | | | | | | |
| | | (MW > 1,000) | | | | | | | | | | |
| | Photocationic | CPI-210S | 0.5 | 0.5 | 0.5 | 0.5 | 0.5 | 0.5 | | 0.5 | 0.5 | 0.5 |
| | polymerization | | | | | | | | | | | |
| | initiator (C) | | | | | | | | | | | |
| | Thermalcationic | CXC-1612 | 0.1 | 0.1 | 0.1 | 0.1 | 0.1 | | 0.1 | 0.1 | 0.1 | 0.1 |
| | polymerization initiator (D) | | | | | | | | | | | |
| | (D)/(C)** × 100 | | 20 | 20 | 20 | 20 | 20 | — | 20 | 20 | 20 | 20 |
| Evalu- | Viscosity at 25° C. (mPa · s) | 25° C., 20 rpm | 14 | 13 | 16 | 18 | 14 | 14 | 14 | 14 | 13 | 14 |
| ation | Surface tension (mN/m) | | 25 to 35 | | | | | | | | | |
| | Patterning retention | Change after 30 | Good | Good | Good | Good | Good | Poor | Poor | Good | Good | Good |
| | | min at 150° C. | | | | | | | | | | |
| | Adhesion after PCT | 121° C., 100% | Good | Good | Good | Good | Poor | Poor | Poor | Fair | Fair | Fair |
| | (cross-cut test) | RH, 96 hr | | | | | | | | | | |

| | | | | | | | | | | |
|---|---|---|---|---|---|---|---|---|---|---|
| Absolute value of difference in coefficient of | 19 | — | — | — | — | — | — | — | — | — |
| linear expansion between 150° C. and 25° C. | | | | | | | | | | |
| Total amount of anions detected when 0.25 g | 12 | — | — | — | — | — | — | — | — | — |
| of cured product is immersed in 10 mL of | | | | | | | | | | |
| water at 100° C. and subjected to extraction | | | | | | | | | | |
| for 20 hours (ppm) | | | | | | | | | | |
| pH of water after 0.25 g of cured product is | 5.2 | — | — | — | — | — | — | — | — | — |
| immersed in 10 mL of water at 100° C. and | | | | | | | | | | |
| left for 20 hours | | | | | | | | | | |
| Water absorption percentage of | 0.9 | — | — | — | — | — | — | — | — | — |
| cured product (%) | | | | | | | | | | |

*MW: Molecular weight,
**(D)/(C): Thermalcationic polymerization initiator (D)/Photocationic polymerization initiator (C)

As shown in Tables 1 and 2, both patterning retention after thermal curing and adhesion after PCT were excellent in Examples 1 to 4 that contain a particular cationic polymerizable compound (A), a particular silane coupling agent (B), a photocationic polymerization initiator (C), and a thermalcationic polymerization initiator (D) (Examples 1 to 8). It is inferred that the Si—O—Si bonds of the particular silane coupling agent (B) are oriented at the interface between the board and the cured product, thereby increasing the adhesion.

In contrast, adhesion after PCT was low when a silane coupling agent had a low molecular weight and did not contain Si—O—Si bonds, or when the silane coupling agent itself was not contained (Reference Examples 1 to 13).

Further, adhesion after PCT was not sufficient when a composition contained only the photocationic polymerization initiator (C) (Reference Examples 2 and 9). In addition, when a composition contained only the thermalcationic polymerization initiator (D), the composition cannot be temporarily cured, and the patterning retention became low (Reference Examples 3 and 10).

2. Second Composition

2-1. Material

(K) Alicyclic Epoxy Compound
Celloxide 8010 (manufactured by Daicel Corporation, Compound having two cycloalkene oxide structures represented by the following structural formula)

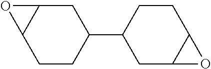 [SMILES: C1CC2OC2CC1C1CCC2OC2C1]

THI-DE (manufactured by JX-TG, 3,4:7,8-Diepoxybicyclo[4.3.0]nonane represented by the following structural formula)

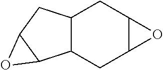 [SMILES: C1C2CC3OC3C2CC2OC12]

(L) (manufactured by Nagase ChemteX Corporation, Limonene dioxide represented by the following structural formula)

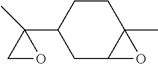

(L) Photocationic Polymerization Initiator
CPI-210S (manufactured by San-Apro Ltd.)
CPI-310FG (manufactured by San-Apro Ltd.)

(M) Silane Coupling Agent
KBM-303 (manufactured by Shin-Etsu Chemical Co., Ltd., 2-(3,4-Epoxy cyclohexyl)ethyltrimethoxysilane)
KBM-403 (manufactured by Shin-Etsu Chemical Co., Ltd., 3-Glycidoxypropyltriethoxysilane)
KR-516 (manufactured by Shin-Etsu Chemical Co., Ltd., Epoxy group-containing alkoxy oligomer)
KR-517 (manufactured by Shin-Etsu Chemical Co., Ltd., Epoxy group-containing alkoxy oligomer)

(N) Additional Components
OXT-221 (manufactured by Toagosei Co., Ltd., 3-Ethyl-3{[(3-ethyloxetane-3-yl)methoxy]methyl}oxetane represented by the following formula)

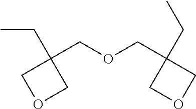

EPOGOSEY NPG (D) (manufactured by Yokkaichi Chemical Company Limited, Neopentyl glycol diglycidyl ether represented by the following structural formula)

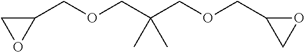

2-2. Preparation of Inkjet Coating-Type Semiconductor Protection Composition

### Example 9

An alicyclic epoxy compound (K), a photocationic polymerization initiator (L), a silane coupling agent (M), and an oxetane compound (OXT-221) at amounts shown in Table 3 were placed in a flask and mixed. The resulting mixture was stirred until no powder was visible to obtain an inkjet coating-type semiconductor protection composition.

### Examples 10 to 16 and Reference Examples 14 and 15

Each inkjet coating-type semiconductor protection composition was obtained in the same manner as in Example 9 except that the amounts of the components were changed so as to have the composition shown in Table 3.

Evaluation

The methods described below were used to evaluate the chloride content, the viscosity, the surface tension, the patterning retention, the adhesion after pressure cooker test (PCT), the ion migration resistance, and the loss tangent (tan δ) of the obtained inkjet coating-type semiconductor protection composition, the difference between the coefficient of linear expansion at 150° C. and the coefficient of linear expansion at 25° C. of the semiconductor protection member, the total amount of anions detected when the semiconductor protection member was immersed in water for a certain period of time, the pH of water after the semiconductor protection member was immersed in the water for a certain period of time, and water absorption percentage of the semiconductor protection member. Table 3 shows the results.
Chloride Ion Content

An inkjet coating-type semiconductor protection composition was collected in a pressure-resistant container made of polytetrafluoroethylene (PTFE) and weighed, then 10 mL of pure water is added, and the container was sealed tightly. Then, chlorine was heat extracted in an oven at 100° C. (set temperature) for 20 hours. After allowing to cool to room temperature, the extract was recovered and quantitative analysis of chloride ions was carried out by an ion chromatograph method (1C method) with an analyzer (1C. 1CS-3000, manufactured by Thermo Fisher Scientific). Further, although not shown in Table 3, the quantitative analysis of the contents of fluoride ions and bromine ions was also carried out in the same manner, and both of the contents were 50 ppm or less.
Viscosity

The viscosity was measured at 25° C. and 20 rpm by using an E-type viscometer.
Surface Tension

The surface tension was measured at 25° C. by the Wilhelmy method.
Patterning Retention

An ink tank of an inkjet device was filled with each inkjet coating-type semiconductor protection composition. The inkjet device was used to apply the inkjet coating-type semiconductor protection composition to a copper plate and to a 10 cm square SiON sputtered glass. The application pattern was a 5 cm square. The application was performed in such a way that the application amount was 7 pL/drop and the application interval between drops was 30 μm to have a film thickness of 10 μm.

Within 60 seconds after the inkjet coating-type semiconductor protection composition was applied, the obtained coating film was irradiated with ultraviolet light (wavelength: 365 nm, irradiation light amount: 1,000 mJ/cm²). The coating film was then heated at 150° C. for 30 minutes for thermally curing to form a film with a thickness of 10 μm. The shape of the cured film after the thermal curing was visually checked and evaluated as follows:

Good: The change of application pattern on each side after thermal curing was within ±5%.

Fair: The change of application pattern on each side after thermal curing was beyond ±5% and within ±10%.

Poor: The change of application pattern on each side after thermal curing was beyond ±10%.
Adhesion after Pressure Cooker Test (PCT)

An ink tank of an inkjet device was filled with each inkjet coating-type semiconductor protection composition. The inkjet device was used to apply the inkjet coating-type semiconductor protection composition to a copper plate and to SiON sputtered glass. The application pattern was a 5 cm square. The application was performed in such a way that the application amount was 7 pL/drop and the application interval between drops was 30 μm to have a film thickness of 10 μm.

Within 60 seconds after the inkjet coating-type semiconductor protection composition was applied, the obtained coating film was irradiated with ultraviolet light (wavelength: 365 nm, irradiation light amount: 1,000 mJ/cm²). The coating film was then heated at 150° C. for 30 minutes for thermally curing to form a film with a thickness of 10 μm.

The obtained test piece was stored in highly accelerated stress test system (EHS-222, manufactured by ULVAC, Inc.) at 121° C. and 100% Rh for 96 hours to perform the pressure cooker test (PCT). Then, a grid pattern peeling test (cross-cut test) was performed in accordance with ISO 2409, and the adhesion of the cured film was evaluated according to the following criteria:

Good: Number of remaining squares was 95 to 100/100.

Fair: Number of remaining squares was 50 to 94/100.

Poor: Number of remaining squares was 0 to 49/100.
Ion Migration Resistance

The inkjet coating-type semiconductor protection composition was applied to a board including a comb-shaped electrode and cured in the same manner as in the case of the evaluation of the patterning retention. The test was performed on the board using the Electro-chemical migration evaluation system (AMI, manufactured by ESPEC CORP) under the conditions below. The resistance value between the electrodes was measured and evaluated as described below.

Test condition
Temperature: 130° C.
Humidity: 85% RH
Voltage between electrodes: 10V
Test duration: 96 hours

Evaluation Criteria

Good: The resistance between electrodes was more than 1×10⁵Ω

Poor: The resistance between electrodes was 1×10⁵Ω or less
Measurement of Loss Tangent (Tan δ)

A coating film of each inkjet coating-type semiconductor protection composition was formed on release paper by using an applicator. The thickness of the coating film was set to 100 μm. The coating film was irradiated with light having a wavelength of 395 nm at 450 mW/cm² and cured at 150° C. for 30 minutes. The loss tangent (tan δ) at 25° C. to 150° C. was then checked when dynamic viscoelasticity measurement (measuring device: DM6100 manufactured by Seiko Instruments Inc.) was performed at a frequency of 1.6 Hz after curing the coating film at 150° C. for 30 minutes.
Absolute Value of Difference Between Coefficient of Linear Expansion at 150° C. and Coefficient of Linear Expansion at 25° C. of Semiconductor Protection Member

A coating film of each inkjet coating-type semiconductor protection composition was formed on release paper by using an applicator. The thickness of the coating film was set to 100 μm. The coating film was irradiated with light having a wavelength of 395 nm at 450 mW/cm² and cured at 150° C. for 30 minutes. The obtained cured product was peeled off from the release paper, and the temperature-linear expansion coefficient was measured with TMA manufactured by Seiko Instruments Inc. From the measured values, the absolute value of the difference between the coefficient of linear expansion at 150° C. and the coefficient of linear expansion at 25° C. were calculated.
Total Amount of Anions (Ppm) Detected when Semiconductor Protection Member (Cured Product) was Immersed in Water for a Certain Period of Time

A cured product (semiconductor protection member) of the inkjet coating-type semiconductor protection composition was produced in the same manner as in the case of the measurement of the coefficient of linear expansion. First, 0.25 g of the cured product was weighed and placed in a PTFE pressure-resistant container, 10 mL of pure water was added, and the container was sealed tightly. Then, the pressure-resistant container was held in an oven at 100° C. (set temperature) for 20 hours. After allowing to cool to room temperature, the liquid was recovered and quantitative analysis of F⁻, Cl⁻, Br⁻, and SO₄²⁻ was performed by an ion chromatograph method (1C method) to specify the total amount of the anions. 1C. 1CS-3000 (manufactured by Thermo Fisher Scientific) was used in the ion chromatograph method.
The pH of Water after Immersion of Semiconductor Protection Member (Cured Product) in Water for a Certain Period of Time

A cured product (semiconductor protection member) of the inkjet coating-type semiconductor protection composition was produced in the same manner as in the case of the measurement of the coefficient of linear expansion. First, 0.25 g of the cured product was weighed and placed in a PTFE pressure-resistant container, 10 mL of pure water was added, and the container was sealed tightly. Then, the pressure-resistant container was held in an oven at 100° C. (set temperature) for 20 hours. After allowing to cool to room temperature, the liquid was recovered and the pH was measured with a pH meter HM-30G manufactured by DKK-TOA CORPORATION.

Water Absorption Percentage of Semiconductor Protection Member (Cured Product)

A cured product (semiconductor protection member) of the inkjet coating-type semiconductor protection composition was produced in the same manner as in the case of the measurement of the coefficient of linear expansion. The cured product was then pre-dried at 150° C. for 12 hours, and the mass thereof was specified. Subsequently, the cured product was placed in an environment of 23° C. and 70% RH for 24 hours, and the mass of the cured product after moisture absorption was specified. The water absorption was then determined from the change in the mass before and after the moisture absorption percentage.

TABLE 3

| | | | | | | | | | | | | Reference | |
|---|---|---|---|---|---|---|---|---|---|---|---|---|---|
| | | | | Example | | | | | | | | Example | |
| | | | | 9 | 10 | 11 | 12 | 13 | 14 | 15 | 16 | 14 | 15 |
| Compo- | Cationic | CEL8010 | parts by mass | 40 | 40 | 40 | 40 | 40 | 40 | | | | |
| sition | polymerizable | THI-DE | parts by mass | 50 | 50 | 50 | 50 | 50 | 50 | 50 | 70 | 50 | 67 |
| | compound (K) | LDO | parts by mass | | | | | | | 50 | 50 | | |
| | Photocationic | CPI-210S | parts by mass | 0.5 | 0.5 | 0.5 | 0.5 | 0.5 | 0.5 | 0.5 | 0.5 | 0.5 | 0.5 |
| | polymerization | CPI-310FG | parts by mass | | | | | | | | | | |
| | initiator (L) | | | | | | | | | | | | |
| | Silane coupling | KBM-303 | parts by mass | 2 | 10 | | | | 10 | 10 | 10 | 10 | 10 |
| | agent (M) | KBM-403 | parts by mass | | | 10 | | | | | | | |
| | | KR-516 | parts by mass | | | | 10 | | | | | | |
| | | KR-517 | parts by mass | | | | | 10 | | | | | |
| | Additional | OXT-221 | parts by mass | 10 | 10 | 10 | 10 | 10 | 10 | 10 | 10 | 10 | 13 |
| | component (N) | NPG(D) | parts by mass | | | | | | | | | 40 | 20 |

| Evalu- | Chloride content (ppm) | <10 | <10 | <10 | <10 | <10 | <10 | <10 | <10 | 165 | 72 |
|---|---|---|---|---|---|---|---|---|---|---|---|
| ation | Viscosity at 25° C. (mPa · s) | 16 | 14 | 14 | 14 | 14 | 14 | 12 | 12 | 13 | 11 |
| | Surface tension (mN/m) | 25 to 35 | | | | | | | | | |
| | Patterning retention (Change after 30 min | Good | Good | Good | Good | Good | Good | Good | Fair | Poor | Poor |
| | heating at 150° C.) | | | | | | | | | | |
| | Adhesion after PCT (121° C. × | Good | Good | Good | Good | Good | Good | Good | Good | Poor | Poor |
| | 100% RH × 96 hr) | | | | | | | | | | |
| | Ion migration resistance (130° C. × | Good | Good | Good | Good | Good | Good | Good | Good | Poor | Poor |
| | 85% RH × 10 V × 96 hr) | | | | | | | | | | |
| | Loss tangent (tan δ): All areas from 25 | >0.05 | >0.05 | >0.05 | >0.05 | >0.05 | >0.05 | >0.05 | >0.05 | Partly | Partly |
| | to 150° C. | | | | | | | | | < 0.01 | < 0.01 |
| | Absolute value of difference in coefficient | 41 | — | — | — | — | — | — | — | — | — |
| | of linear expansion between 150° C. | | | | | | | | | | |
| | and 25° C. | | | | | | | | | | |
| | Total amount of anions detected when | 24 | — | — | — | — | — | — | — | 176 | — |
| | 0.25 g of cured product is immersed in | | | | | | | | | | |
| | 10 mL of water at 100° C. and subjected to | | | | | | | | | | |
| | extraction for 20 hours (ppm) | | | | | | | | | | |
| | pH of water after 0.25 g of cured product | 5.4 | — | — | — | — | — | — | — | — | — |
| | is immersed in 10 mL of water at 100° C. | | | | | | | | | | |
| | and left for 20 hours | | | | | | | | | | |
| | Water absorption percentage of | 0.9 | — | — | — | — | — | — | — | — | — |
| | cured product (%) | | | | | | | | | | |

As shown Table 3, ion migration was less likely to occur in a inkjet coating-type semiconductor protection composition having a chloride ion content of 50 ppm or less (Examples 9 to 16). It is inferred that as the epoxy compound of the Examples was the alicyclic epoxy compound (K), chlorine derived from the material is less likely to be mixed in, resulting in a low amount of chlorine. In addition, the inkjet coating-type semiconductor protection compositions of the above Examples had suitable patterning retention and suitable adhesion after PCT.

In contrast, ion migration was more likely to occur in a inkjet coating-type semiconductor protection composition having a chloride ion content of more than 50 ppm (Reference Examples 14 and 15).

This application claims priority based on Japanese Patent Application No. 2019-059223, filed on Mar. 26, 2019 and Japanese Patent Application No. 2019-064888 filed on Mar. 28, 2019, the entire contents of which including the specifications are incorporated herein by reference.

### INDUSTRIAL APPLICABILITY

The inkjet coating-type semiconductor protection composition of the present invention is capable of forming a cured product having excellent pattern retention at high temperatures and moisture resistance and also having suitable adhesion to a semiconductor circuit or the like for a long period of time. The inkjet coating-type semiconductor protection composition can be applied by an inkjet method, and thus can be applied efficiently and easily. Therefore, the inkjet coating-type semiconductor protection composition is particularly advantageous for production of various semiconductor devices.

1. A semiconductor protection member, comprising:
a cured product of an organic polymerizable compound comprising a functional group, wherein the functional group comprises at least one of an oxygen atom or a nitrogen atom, and wherein
an absolute value of a difference between a coefficient of linear expansion of the cured product at 150° C. and the coefficient of linear expansion of the cured product at 25° C. is 55 or less.

2. The semiconductor protection member according to claim 1, further comprising:
a Si—O bond at least in a part thereof.

3. The semiconductor protection member according to claim 1, wherein:
a total amount of anions detected when 0.25 g of the cured product is immersed in 10 mL of water at 100° C. and subjected to extraction for 20 hours is 50 ppm or less.

4. The semiconductor protection member according to claim 1, wherein:
pH of water after 0.25 g of the cured product is immersed in 10 mL of the water at 100° C. and left for 20 hours is 4.4 to 8.7.

5. The semiconductor protection member according to claim 1, wherein:
the cured product has a water absorption percentage of 2% or less.

6. The semiconductor protection member according to claim 1, wherein:
the organic polymerizable compound is at least one compound selected from the group consisting of epoxy compounds, urethane compounds, (meth)acrylic compounds, imide compounds, and benzoxazole.

7. An inkjet coating-type semiconductor protection composition, comprising:
a cationic polymerizable compound (A) that contains an epoxy compound having two or more epoxy groups per molecule and an oxetane compound having two or more oxetane groups per molecule;
a silane coupling agent (B) having a Si—O—Si skeleton, an epoxy group, and an alkoxy group per molecule and having a weight average molecular weight of 1,000 or more;
a photocationic polymerization initiator (C); and
a thermalcationic polymerization initiator (D),
wherein
the inkjet coating-type semiconductor protection composition has a viscosity of 5 to 50 mPa·s measured at 25° C. and 20 rpm by using an E-type viscometer.

8. The inkjet coating-type semiconductor protection composition according to claim 7, wherein:
the inkjet coating-type semiconductor protection composition has a surface tension of 20 to 40 mN/m.

9. The inkjet coating-type semiconductor protection composition according to claim 7, wherein:
the silane coupling agent (B) has two or more epoxy groups per molecule, and two or more alkoxy groups per molecule.

10. The inkjet coating-type semiconductor protection composition according to claim 7, wherein:
the inkjet coating-type semiconductor protection composition contains 1 to 20 parts by mass of the silane coupling agent (B), 0.1 to 10 parts by mass of the photocationic polymerization initiator (C), and 0.1 to 10 parts by mass of the thermalcationic polymerization initiator (D), based on 100 parts by mass of the cationic polymerizable compound (A); and
an amount of the thermalcationic polymerization initiator (D) is 10 to 50 parts by mass based on 100 parts by mass of the photocationic polymerization initiator (C).

11. An inkjet coating-type semiconductor protection composition, comprising:
an alicyclic epoxy compound (K) having two or more epoxy groups per molecule;
a photocationic polymerization initiator (L); and
a silane coupling agent (M),
wherein the inkjet coating-type semiconductor protection composition has
chloride ion content of 50 ppm or less, and
a viscosity of 5 to 50 mPa·s measured at 25° C. and 20 rpm by using an E-type viscometer.

12. The inkjet coating-type semiconductor protection composition according to claim 11, wherein:
the inkjet coating-type semiconductor protection composition has a surface tension of 20 to 40 mN/m.

13. The inkjet coating-type semiconductor protection composition according to claim 11, wherein:
the alicyclic epoxy compound (K) has a cycloalkene oxide structure represented by a general formula below 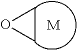
wherein M represents an alicyclic structure having 4 to 8 carbon atoms.

14. The inkjet coating-type semiconductor protection composition according to claim 11, wherein:
the inkjet coating-type semiconductor protection composition contains 0.1 to 10 parts by mass of the photocationic polymerization initiator (L) and 1 to 20 parts by mass of the silane coupling agent (M), based on 100 parts by mass of the alicyclic epoxy compound (K).

15. A cured product of the inkjet coating-type semiconductor protection composition according to claim 11, wherein:
the cured product has a loss tangent (tan δ) of 0.01 or more in a temperature range of 25° C. to 150° C. when dynamic viscoelasticity measurement is performed at a frequency of 1.6 Hz.

16. A semiconductor device, comprising:
a semiconductor circuit board;
a cured product layer of the inkjet coating-type semiconductor protection composition according to claim 7, the cured product layer covering at least a part of the semiconductor circuit board; and
a semiconductor mold resin layer disposed on or above the cured product layer.

17. A semiconductor device, comprising:
a board with metal wiring disposed thereon;
a cured product layer of the inkjet coating-type semiconductor protection composition according to claim 7, the cured product layer covering at least a part of the metal wiring of the board; and
a circuit portion disposed on or above the cured product layer so as to be electrically connected to the metal wiring.

18. A method for producing a semiconductor device, the method comprising:
preparing a semiconductor circuit board or a board including metal wiring;
applying the inkjet coating-type semiconductor protection composition according to claim 7 on the semiconductor circuit board or the metal wiring of the board by an inkjet method;
performing photo curing of a coating film of the inkjet coating-type semiconductor protection composition by irradiating the coating film with active light within 60 seconds after the applying; and
performing thermal curing of the coating film after the photo curing with heat.
